(19) United States
(12) Patent Application Publication
(10) Pub. No.: US 2022/0068803 A1
(43) Pub. Date: Mar. 3, 2022

(54) SEMICONDUCTOR STORAGE DEVICE

(71) Applicant: Kioxia Corporation, Tokyo (JP)

(72) Inventor: Daigo ICHINOSE, Nagoya (JP)

(73) Assignee: Kioxia Corporation, Tokyo (JP)

(21) Appl. No.: 17/179,875

(22) Filed: Feb. 19, 2021

(30) Foreign Application Priority Data
Aug. 31, 2020 (JP) 2020-146303

(51) Int. Cl. H01L 23/522; H01L 23/528; H01L 27/11556; H01L 27/11529; H01L 27/11582; H01L 27/11573

(52) U.S. Cl. CPC H01L 23/5226; H01L 23/5283; H01L 27/11573; H01L 27/11529; H01L 27/11582; H01L 27/11556

(57) ABSTRACT

A semiconductor storage device includes a stacked body where first layers of a first insulating material, and second layers are stacked alternately, and plate-like portions penetrating through the stacked body in a stacking direction thereof and extending in a first direction intersecting the stacking direction. Each second layer includes a first insulating area and an electrically conductive area, the former extending from a first edge portion of the stacked body in the first direction thereby occupying at least an area between a first edge portion of each plate-like portions and the first edge portion of the stacked body, and the latter being connected to the first insulating area in the first direction. A boundary between the first insulating area and the electrically conductive area is located farther from the first edge portion of plate-like portions along the first direction with respect to the first edge portion of the stacked body.

### CROSS-REFERENCE TO RELATED APPLICATIONS

This application is based upon and claims the benefit of priority from Japanese Patent Application No. 2020-146303, filed on Aug. 31, 2020; the entire contents of which are incorporated herein by reference.

### FIELD

Embodiments of the present disclosure relate to a semiconductor storage device.

### BACKGROUND

Some semiconductor storage devices having, for example, a three-dimensional structure may have a stacked body where plural insulating layers and plural electrically conductive layers are stacked alternately one on the other, memory pillars that penetrate through the stacked body, and plural memory cells formed in the memory pillars. Here, the electrically conductive layers function as word lines of corresponding ones of the memory cells. Contacts are provided to the corresponding electrically conductive layers in order to connect the electrically conductive layers serving as the word lines with control circuits and the like that control the memory cells. These contacts are connected to the corresponding electrically conductive layers that appear as terrace surfaces by processing an edge portion of the stacked body into a shape of stairs.

Such a shape of stairs tends to be provided in a central portion of the stacked body rather than in the edge portion of the stacked body, in order to lower the resistance of the word line and to speed up an operation of the semiconductor storage device. Under such tendency, attention has been attracted about how the edge portion of the stacked body is constructed.

### BRIEF DESCRIPTION OF THE DRAWING

FIG. 1 is a top plan view schematically illustrating one example of the semiconductor storage device according to the first embodiment;

FIG. 2 is an enlarged top view schematically illustrating a stair area of a memory portion of the semiconductor storage device in FIG. 1;

FIG. 3 is a cross-sectional view taken along an A1-A1 line in FIG. 2;

FIG. 4 is a cross-sectional view taken along an A2-A2 line in FIG. 2;

FIG. 5A is an enlarged top view schematically illustrating a slit terminating area;

FIG. 5B is a cross-sectional view taken along an L6-L6 line in FIG. 5A;

FIGS. 6A to 6E are cross-sectional views taken along corresponding cutting-plane lines in FIG. 5;

FIGS. 7A to 7E are top plan views for explaining a forming method of the slit terminating area;

FIGS. 8A to 8C are views schematically illustrating cross sections of a stacked body;

FIG. 9 is a top plan view schematically illustrating a silicon nitride layer in the stacked body;

FIGS. 10A to 10C are explanatory views illustrating the slit terminating area of a semiconductor storage device according to a comparative example 1;

FIG. 11 is a top plan view illustrating an electrically conductive layer in the slit terminating area in the Comparative Example 1;

FIGS. 12A and 12B are top plan views schematically illustrating a relationship between an etching length of the silicon nitride layer and a length of a barrier layer within a slit;

FIGS. 13A to 13C are explanatory views for explaining the slit terminating area of a semiconductor storage device according to Comparative Example 2;

FIG. 14A is a top plan view schematically illustrating a center portion of the semiconductor storage device according to the first embodiment;

FIG. 14B is a cross-sectional view schematically illustrating an edge portion extending along a longitudinal direction in the semiconductor storage device according to the first embodiment;

FIG. 15A is a top plan view schematically illustrating an example of a semiconductor storage device according to a second embodiment;

FIG. 15B is a partial cross-sectional view schematically illustrating an edge portion of the semiconductor storage device according to the second embodiment;

FIG. 16 is a cross-sectional view of an edge portion and the proximity thereof, the edge portion extending along a long direction in a semiconductor storage device according to a third embodiment, taken along a short direction;

FIG. 17 is a cross-sectional view of an edge portion and the proximity thereof, the edge portion extending along the longitudinal direction in a semiconductor storage device according to Modification 1 of the third embodiment, taken along a short direction;

FIG. 18 is a cross-sectional view of an edge portion extending in a longitudinal direction of a semiconductor storage device according to Modification 2 of the third embodiment, taken along a short direction;

FIG. 19 is a top plan view illustrating a stair area of a semiconductor storage device according to a first modification;

FIG. 20A is a cross-sectional view taken along an A3-A3 line in FIG. 19;

FIG. 20B is a cross-sectional view taken along an A4-A4 line in FIG. 19; and

FIG. 21 is a cross-sectional view schematically illustrating a slit terminating area in a second modification.

### DETAILED DESCRIPTION

According to one embodiment of the present disclosure, a semiconductor storage device is provided. The semiconductor storage device includes a stacked body in which a plurality of first layers and a plurality of second layers are stacked alternately one on another, and a plurality of plate-like portions that penetrate through the stacked body in a stacking direction of the stacked body and extend in a first direction intersecting the stacking direction. The plurality of first layers are formed of a first insulating material. Each of the plurality of second layers includes a first insulating area and an electrically conductive area. The first insulating area is arranged to extend from a first edge portion of the stacked body in the first direction so that the first insulating area occupies at least an area between a first edge portion of each of the plurality of plate-like portions extending in the first direction and the first edge portion of the stacked body in the first direction. The first insulating area is formed of a second insulating material. The electrically conductive area is connected to the first insulating area in the first direction. A boundary portion between the first insulating area and the electrically conductive area is located farther from the first edge portion of each of the plurality of plate-like portions along the first direction with respect to the first edge portion of the stacked body.

Non-limiting, exemplary embodiments of the present invention will now be described with reference to the accompanying drawings. In the drawings, the same or corresponding reference marks are given to the same or corresponding members or components, and redundant explanations will be omitted. It is to be noted that the drawings are illustrative of the invention, and there is no intention to indicate scale or relative proportions among the members or components, or between thicknesses of various layers. Therefore, the specific thickness or size should be determined by a person having ordinary skill in the art in view of the following non-limiting embodiments.

### First Embodiment

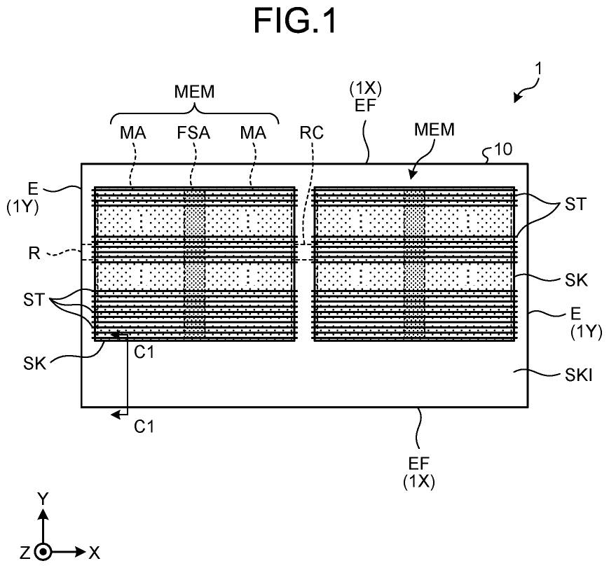

FIG. 1 is a top plan view schematically illustrating an example of a semiconductor storage device according to a first embodiment. As illustrated in FIG. 1, a semiconductor storage device 1 has a substrate 10 of chip shape. On the substrate 10, a peripheral circuit portion described below is formed, and on the peripheral circuit portion, a stacked body portion is formed which includes a stacked body SK and a stacked body SKI. The stacked body SK has a structure where electrically conductive layers and insulating layers are stacked alternately one on the other, and the stacked body SKI has a structure where insulating layers different from each other are stacked alternately one on the other. As illustrated in FIG. 1, the semiconductor storage device 1 has two stacked bodies SK arranged next to each other along a long direction (an X-axis direction), in each of which memory portions MEM (also known as planes) are formed. Additionally, the semiconductor storage device 1 has the stacked body SKI around the two stacked bodies SK. Namely, the stacked body SKI surrounds the stacked bodies SK and has edge portions E extending in a Y-axis direction and edge portions EF extending in the X-axis direction. In this embodiment, the edge portion E of the stacked body SKI corresponds to an edge portion 1Y of the semiconductor storage device 1, and the edge portion EF corresponds to an edge portion 1X of the semiconductor storage device 1. Therefore, the stacked body SKI appears on both edge portion surfaces of the semiconductor storage device 1 according to this embodiment.

In the memory portion MEM, a memory array area MA, a stair area FSA, another memory array area MA are arranged in this order along the X-axis direction. Namely, the stair area FSA is placed in a central portion of the memory portion MEM, and thus interposed between the two memory array areas MA. A plurality of memory cells are provided three-dimensionally in the memory array area MA. The stair area FSA is provided with contacts electrically connecting to gates of the memory cells, and through-contacts and the like electrically connecting the contacts with the peripheral circuit. The peripheral circuit controls operation of the memory cells. The peripheral circuit may include, for example, a row decoder and a sense amplifier circuit. The row decoder identifies an area that includes the memory cells to be operated; and the sense amplifier circuit senses the data held by the memory cells. Note that the stair area FSA, while being provided in the stacked body SK, locally includes the stacked body SKI as described below.

The semiconductor storage device 1 is provided with slits ST that extend in the X-axis direction in FIG. 1 and divide the memory portion MEM in the Y-axis direction.

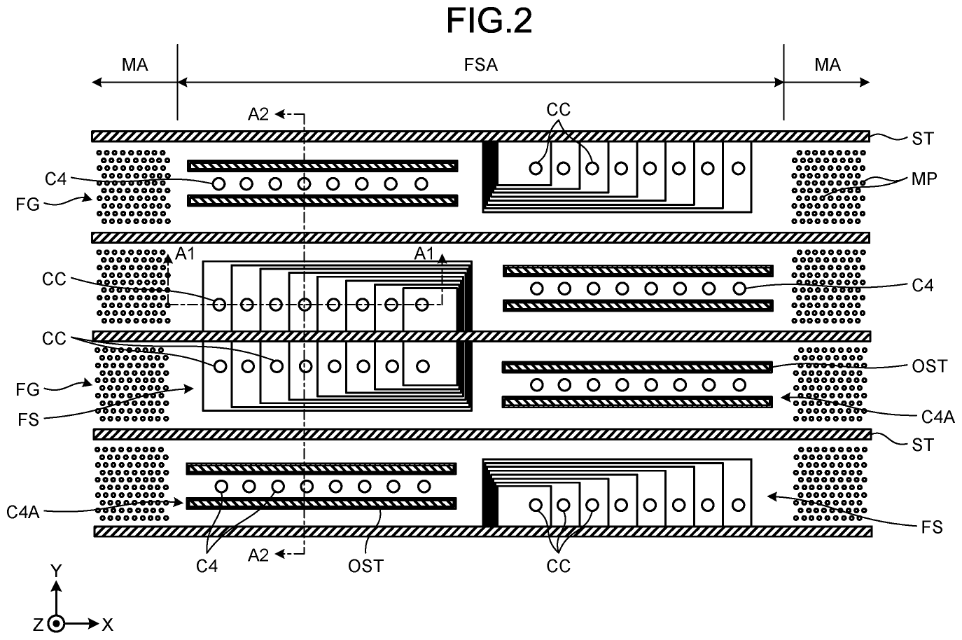

Referring to FIG. 2, a structure of the stair area FSA is described as follows. FIG. 2 is an enlarged top view schematically illustrating the stair area FSA. Here, upper-layer lines and the like are omitted in FIG. 2. As illustrated in FIG. 2, a pair of a stair portion FS and a through-contact area C4A are provided in each of finger areas FG defined by the two adjacent slits ST. The stair portion FS and the through-contact area C4A each has an elongated shape in the X-axis direction, and are arranged next to each other along the X-axis direction. Note that, in the memory array areas MA on both sides of the stair area FSA, plural memory pillars MP penetrating through the stacked body SK in the stacking direction (a Z-axis direction) are provided as illustrated in the drawing. A plurality of memory cells are formed respectively at positions where plural electrically conductive layers (described later) of the stacked body SK extending from the stair area FSA intersect the memory pillars MP.

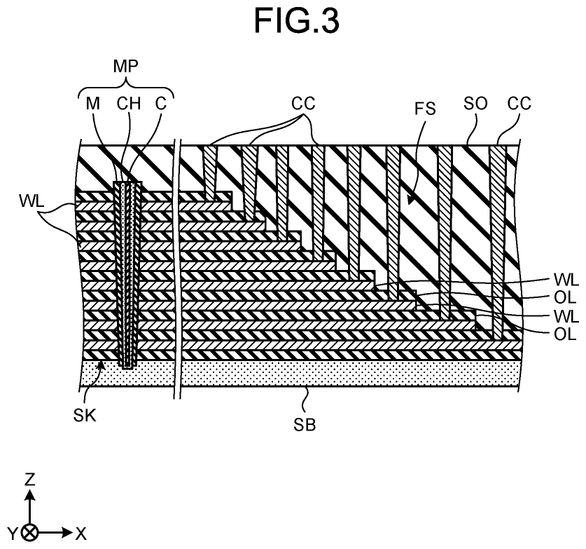

FIG. 3 is a cross-sectional view taken along an A1-A1 line in FIG. 2. Here, the peripheral circuit portion and the like below the stacked body SK is omitted in FIG. 3. The stair portion FS has a shape of stairs where a pair of an electrically conductive layer WL and an insulating layer OL corresponds to one step, with the insulating layer OL as a terrace surface (tread surface), and widths (lengths in the X-axis direction) of the upper steps become shorter. Above the stair portion FS, an inter-layer insulation layer SO is formed. Contacts CC, which penetrate through the inter-layer insulation layer SO and the insulating layer OL of each step, are connected to the corresponding electrically conductive layers WL. Here, the electrically conductive layers WL extend also to the memory array area MA, and are opposed to the memory pillars MP in the memory array area MA. The memory pillars MP penetrate through the stacked body SK where the electrically conductive layers WL and the insulating layers OL are stacked alternately one on the other, and reach a base layer SB serving as a source electrode for each memory cell. Each one of the memory pillars MP has a core layer C, a channel layer CH, and a memory film M that are provided to be superposed from the center toward the outside. The channel layer CH protrudes below the memory film M with respect to the base layer SB, and is electrically connected to the base layer SB. Among the plural electrically conductive layers WL, at least the uppermost electrically conductive layer WL and at least the lowermost electrically conductive layer WL, which are opposed to the memory pillars MP, serve as select gate lines, and the rest of the electrically conductive layers WL therebetween function as gate electrodes (i.e., word lines) of the memory cells.

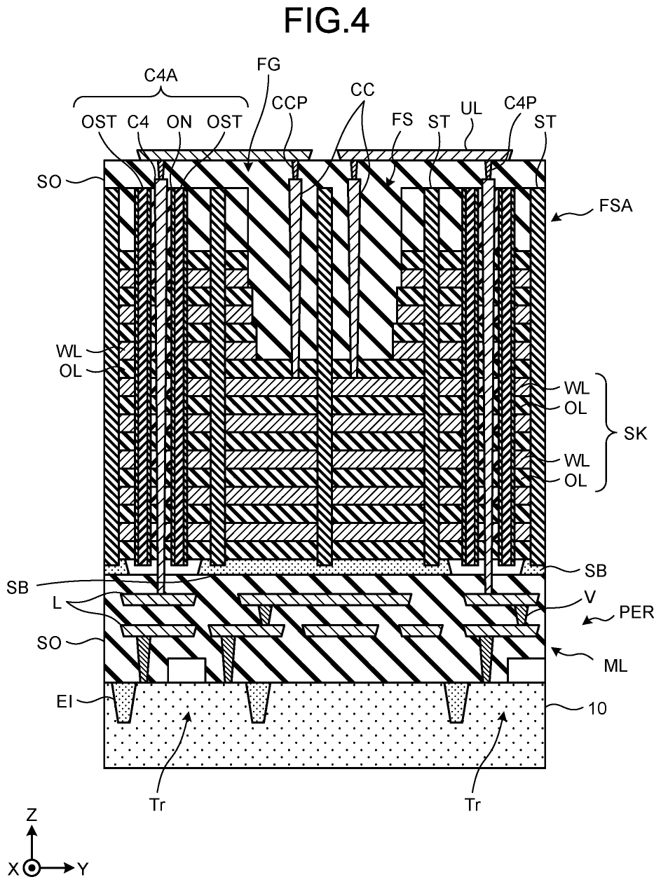

FIG. 4 is a cross-sectional view taken along an A2-A2 line in FIG. 2. As illustrated, a multilayered line portion ML is formed on the substrate 10. Transistors Tr are formed in the substrate 10 so as to be isolated by element-isolating portions EI. Lines L and vias V are provided in the multilayered line portion ML, or specifically within the inter-layer insulation layer SO. A peripheral circuit portion PER is formed of the transistors Tr in the substrate 10, and the lines L and the vias V in the multilayered line portion ML. Additionally, on the multilayered line portion ML, the base layer SB is formed, for example, of silicon or the like, and the stacked body SK is formed on the base layer SB. The stacked body SK has the plural insulating layers OL and the plural electrically conductive layers WL that are stacked alternately one on the other. The insulating layers OL are formed of, for example, an insulating material, or silicon oxide in this embodiment. In the following description, the insulating layer OL is called a silicon oxide layer OL. In addition, the electrically conductive layer WL may be formed of, for example, metal such as tungsten, molybdenum, or the like.

The slits ST penetrate through the stacked body SK and reach the base layer SB. An insulating material such as silicon oxide and the like are filled into the slits ST. An electrically conductive material may be filled into the slits ST of which sidewall has been covered by an insulating material. In this case, the electrically conductive material may function as a source line contact by being connected to the base layer SB. The stair portions FS are formed respectively in the finger areas FG on both sides of the central slit ST in the drawing. The through-contact areas C4A are formed respectively in the finger areas FG that are further outside the finger areas FG that have the stair portion FS formed therein. Here in FIG. 4, the contact CC is illustrated which is connected to the terrace surface of the fifth step of the stair portion FS from the bottom.

The through-contact areas C4A are provided with two short slits OST, an insulating layer area ON provided between the two short slits OST, and through-contacts C4 that penetrate through the insulating layer area ON and the base layer SB. Although the short slits OST extend in the X-axis direction as with the slits ST, the short slits OST are shorter than the slits ST, as illustrated in FIG. 2. A barrier layer (not illustrated) is formed on an inner surface of the short slit OST, and the inner area thereof is filled with an insulating material such as silicon oxide or the like. In the insulating layer area ON, plural silicon oxide layers and plural silicon nitride layers are stacked alternately one on the other, for example. With this, the insulating layer area ON is electrically insulative as a whole. Therefore, the through-contact C4 penetrating through the insulating layer area ON is electrically insulated from the electrically conductive layers WL in the stacked body SK. The through-contact C4 is electrically connected at a bottom end thereof to the line L of the peripheral circuit portion PER, and further to the peripheral circuit through the via V and the like. Additionally, the through-contact C4 is connected at a top end thereof to an upper-layer line UL through a plug C4P, and the upper-layer line UL is electrically connected to the contact CC through a plug CCP. Because the contact CC is electrically connected to the memory cells through the electrically conductive layer WL, the memory cells are electrically connected to the peripheral circuit.

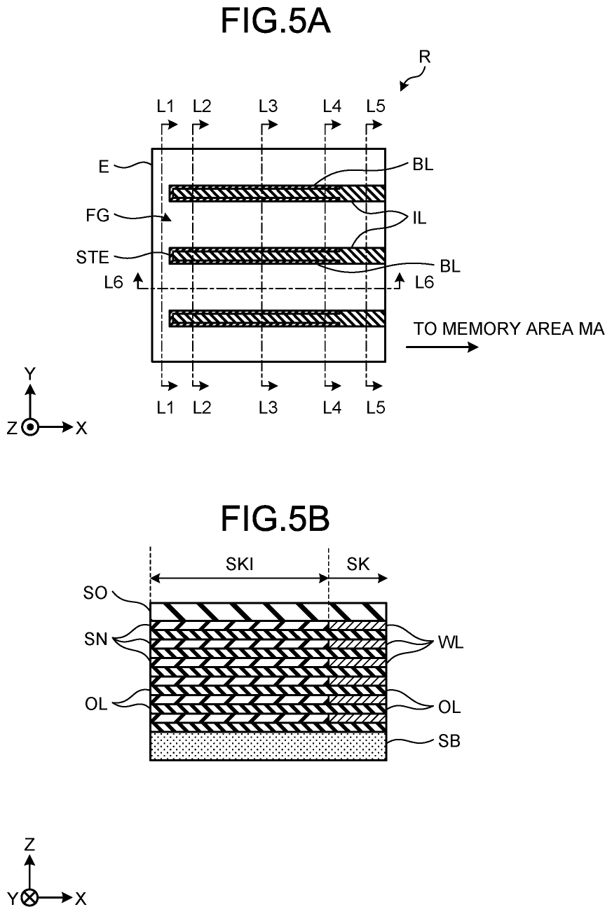

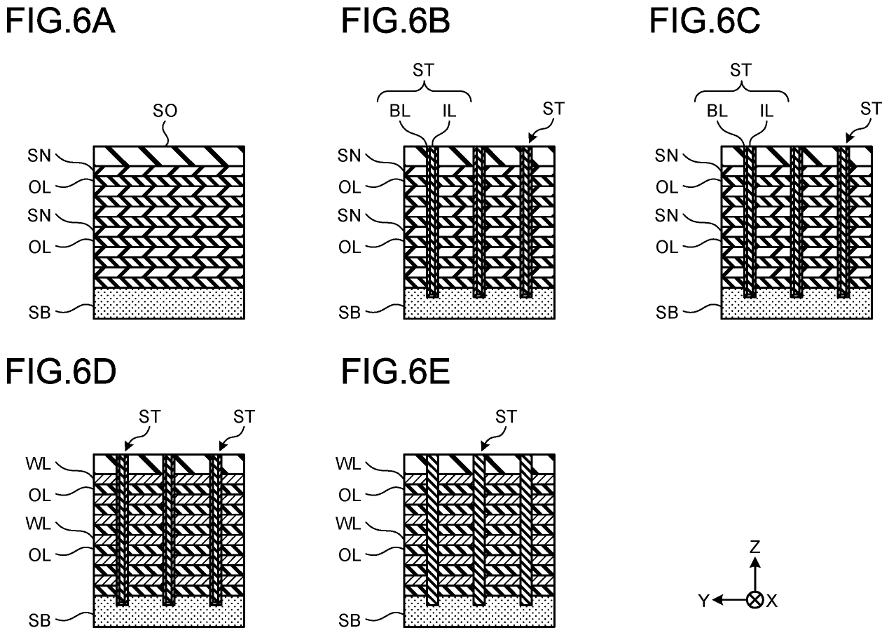

Next, referring to FIGS. 5A to 6E, an explanation is made on a structure in an area between the edge portion E of the stacked body portion (stacked body SKI) and the memory array area MA. This area is an area R indicated in, for example, FIG. 1, and is referred to as a slit terminating area R in the following, for the sake of convenience. FIG. 5A is an enlarged top view of the slit terminating area R; and FIG. 5B is a cross-sectional view taken along an L6-L6 line in FIG. 5A. Additionally, FIGS. 6A, 6B, 6C, 6D, and 6E are cross-sectional views taken along an L1-L1 line, an L2-L2 line, an L3-L3 line, an L4-L4 line, and an L5-L5 line in FIG. 5A, respectively.

As illustrated in FIG. 5A, each of the slits ST has an edge portion STE in a position spaced apart from the edge portion E of the stacked body portion (stacked body SKI) by a predetermined distance, and extends in the X-axis direction. A barrier layer BL is formed on the inner surface of the slit ST, and an insulating layer IL is formed inside the barrier layer BL. Namely, a plate-like portion, which includes the barrier layer BL and the insulating layer IL, is defined by the slit ST. Note that when an electrically conductive material is filled into the slit ST to allow the slit ST to function as the source line contact by connecting this electrically conductive material to the base layer SB, as mentioned above, such an electrically conductive material may be filled inside the barrier layer BL serving as the insulating layer. Additionally, the stacked body SKI and the stacked body SK are formed next to each other in the X-axis direction on the base layer SB in the finger area FG of the slit terminating area R as illustrated in FIG. 5B. The edge portions STE of the above-mentioned slits ST are located within the stacked body SKI, as can be seen from FIG. 5A and FIG. 5B. Namely, the area between the edge portion E and the edge portions STE of the slits ST in the X-axis direction is occupied by the stacked body SKI rather than the stacked body SK. Additionally, as illustrated in FIG. 5B, the silicon oxide layers OL of the stacked body SKI are connected to the corresponding silicon oxide layers OL of the stacked body SK, and thus formed as single bodies. On the other hand, the electrically conductive layers WL of the stacked body SK are connected to corresponding silicon nitride layers SN of the stacked body SKI. Therefore, in the slit terminating area R, the plural silicon oxide layers OL are arranged, with spaces being between the two adjacent silicon oxide layers OL. In the spaces, the silicon nitride layers SN extend to a predetermined length from the edge portion E in the X-axis direction, and the electrically conductive layers WL are connected to the corresponding silicon nitride layers SN and extend in the X-axis direction.

Note that, in this embodiment, boundaries between the silicon nitride layers SN and the electrically conductive layers WL are aligned in the stacking direction of the stacked bodies SKI, SK, as illustrated in FIG. 5B. Additionally, a stacking structure of the stacked body SKI is the same as a stacking structure of the above-mentioned insulating layer area ON. Specifically, the stacking number of the silicon oxide layers OL and the silicon nitride layers SN and the thickness of each layer are approximately equal in the stacked body SKI and the insulating layer area ON. Note that the stacking number may be determined arbitrarily, without limiting to that in an illustrated example.

Referring to FIG. 6A, the stacked body SKI is formed on the base layer SB. This drawing is a cross-sectional view taken along the L1-L1 line in FIG. 5A, and a Y-Z cross-sectional view of a separating area between the edge portion STE of the slit ST and the edge portion E of the stacked body portion (stacked body SKI). On the other hand, FIGS. 6B and 6C illustrate the slits ST. The slits ST penetrate through the stacked body SKI and reach the base layer SB. Additionally, these slits ST each have the barrier layer BL and the insulating layer IL.

Referring to FIG. 6D, which is a cross-sectional view taken along the L4-L4 in FIG. 5A, the stacked body SK rather than the stacked body SKI is formed on the base layer SB. The plural slits ST penetrate through the stacked body SK. Each of these slits ST has the barrier layer BL and the insulating layer IL as with that illustrated FIGS. 6B and 6C.

In FIG. 6E, the plural slits ST penetrate through the stacked body SK as with those in FIG. 6D. However, these slits ST are provided with no barrier layers BL but only the insulating layers IL.

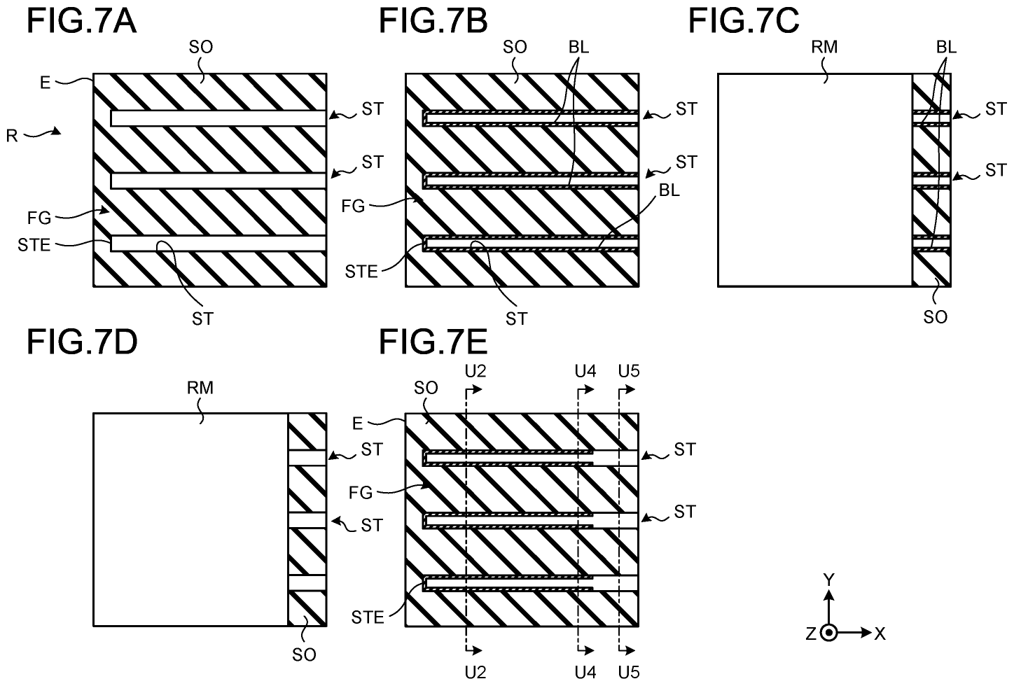

Then, referring to FIGS. 7A to 7E, a forming method of the structure of the slit terminating area R is described. FIGS. 7A to 7E are top plan views for explaining the forming method of the structure of the slit terminating area R.

Note that a manufacturing process of the semiconductor storage device 1 performed prior to the forming method of the slit terminating area R is outlined as follows. First, the above-mentioned peripheral circuit portion PER is formed, for example, on a semiconductor substrate such as a silicon wafer and the like. Then, the base layer SB is formed on the peripheral circuit portion PER, and, thereupon, the stacking structure (such as the above-mentioned stacked body SKI) where the plural silicon oxide layers OL and the plural silicon nitride layers SN are stacked alternately one on the other is formed. Then, on the top surface of the stacking structure, a resist mask is provided which has openings at positions where the stair portions FS are to be formed, and a temporary stair portion is formed by a process step including, for example, etching, slimming of the resist mask, and additional etching. In the temporary stair portion, the silicon oxide layers OL within the stacking structure are arranged as the terrace surface. After this, a silicon oxide film is deposited, for example, to cover the temporary stair portion and the stacking structure. Then, this silicon oxide film is planarized, and a silicon oxide film SO (FIG. 5B) is obtained as the inter-layer insulation layer. The plural memory pillars MP (FIG. 3) penetrating through the stacking structure are formed in the memory array area MA (FIG. 1). The memory pillars MP are formed by forming, for example, memory holes that penetrate through the stacking structure and reach the base layer SB, and by sequentially forming the memory film M (FIG. 3), the channel layer CH, and the core layer C on the inner surface of the memory hole.

Subsequently, the structure of the slit terminating area R is formed. Specifically, first, the plural slits ST are formed as illustrated in FIG. 7A. Here, the slits ST are formed to traverse the memory portion MEM as a whole in the X-axis direction, as illustrated in FIG. 1, and to penetrate through the silicon oxide film SO and the stacked body SKI, thereby to reach the base layer SB (see FIG. 4, for example). Note that the above-mentioned short slits OST (FIGS. 2, 4) may be formed simultaneously with the slits ST.

Then, as illustrated in FIG. 7B, the barrier layers BL are deposited fully on the inner surface of the corresponding slits ST. The barrier layers BL are formed of a material having resistance to etching solution used to etch the silicon nitride layers SN described later. Such a material may be, for example, silicon oxide. Then, as illustrated in FIG. 7C, a resist mask RM is formed on a top surface of the silicon oxide film SO. The resist mask RM covers a portion of the silicon oxide film SO, the portion having a predetermined length from the edge portion E of the stacked body SKI. Therefore, the silicon oxide film SO and the slits ST and the like are exposed in an area beyond the portion toward the memory array area MA.

Note that the barrier layer BL is also deposited on the inner surface of the short slit OST formed simultaneously with the slit ST. The resist mask RM can cover the two short slits OST (FIGS. 2, 4) that are adjacently formed in the finger area FG.

Next, as illustrated in FIG. 7D, the barrier layers BL deposited in the slits ST are removed by etching using the resist mask RM. After this, when the resist mask RM is removed by ashing and the like, the slits ST are obtained which have the barrier layers BL remained partially.

Then, using such slits ST, the silicon nitride layers SN in the stacked body SKI are etched. Specifically, the etching solution capable of dissolving silicon nitride is injected into the slits ST. As for such an etching solution, phosphoric acid (H₃PO₄) is exemplified.

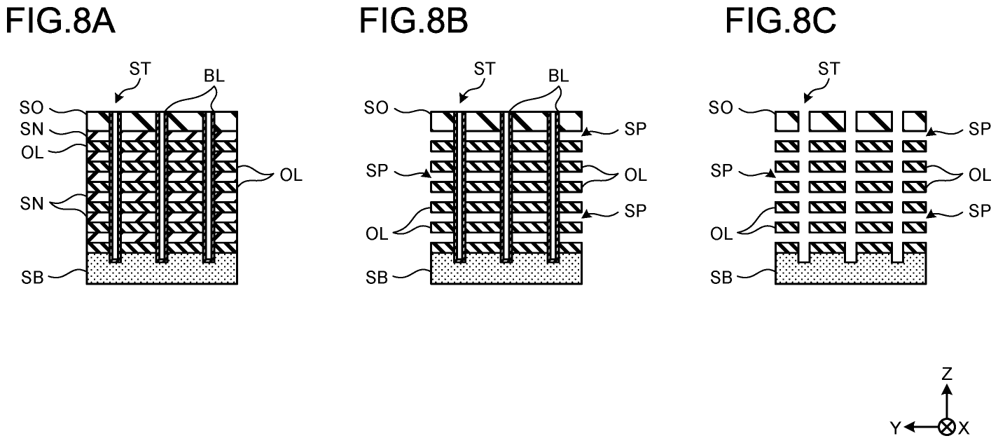

FIGS. 8A to 8C are views schematically illustrating a cross section of the stacked body after the etching. FIG. 8A is a cross-sectional view taken along a U2-U2 line in FIG. 7E; FIG. 8B is a cross-sectional view taken along a U4-U4 line in FIG. 7E; and FIG. 8C is a cross-sectional view taken along a U5-U5 line in FIG. 7E. Note that the U2-U2 line corresponds to the L2-L2 line in FIG. 5A; the U4-U4 line corresponds to the L4-L4 line in FIG. 5A; and the U5-U5 line corresponds to the L5-L5 line in FIG. 5A.

First, referring to FIG. 8C, the plural silicon oxide layers OL are arranged in a vertical direction, with a space SP intervened between every two adjacent ones of the silicon oxide layers OL. The space SP is formed by etching the silicon nitride layers SN. Namely, the silicon nitride layers SN are exposed on the inner surface of the slits ST before the etching, and the silicon nitride layers SN are removed from the exposed surfaces by an etching solution injected into the slits ST. With this, the spaces SP are formed. Note that, after the silicon nitride layers SN are removed, the silicon oxide layers OL are supported by the memory pillars MP in the memory array area MA, plural supporting pillars (not illustrated), and the barrier layer BL in the slit ST. The supporting pillars here are formed by forming holes penetrating through the stacking structure (stacked body SKI) where the plural silicon oxide layers OL and the plural silicon nitride layers SN are stacked alternately one on the other, and filling an insulating material such as silicon oxide into the holes in the stair area FSA and the like. However, an insulating film may be formed on the inner surface of the hole, and an electrically conductive material may be filled thereinside.

On the other hand, in FIG. 8A, the plural silicon oxide layers OL and the plural silicon nitride layers SN are stacked alternately one on the other between the slits ST. This is because the silicon nitride layers SN are prevented from being etched by the barrier layers BL on the inner surfaces of the slits ST.

Note that the silicon nitride layers SN are not etched between the two short slits OST formed adjacently in the finger area FG illustrated in FIGS. 2 and 4, because the barrier layers BL are also deposited in the short slits OST as mentioned above. Therefore, the silicon nitride layers SN are not removed, and thus the insulating layer area ON remains as it is.

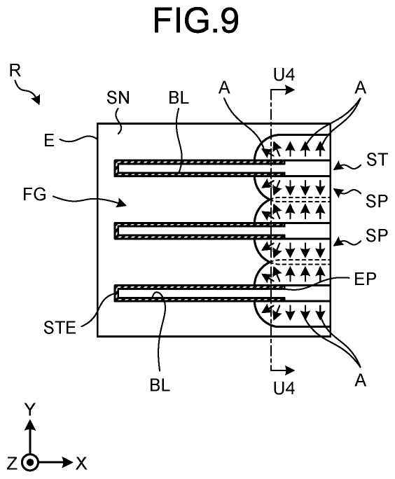

Next, referring to FIG. 8B, despite that the barrier layer BL is formed on the inner surface of the slit ST, the silicon nitride layers SN are removed, which then forms the spaces SP. This is because the etching of the silicon nitride layers SN proceeds from a portion having no barrier layer BL in the slit ST to this part. Referring to FIG. 9, it is explained how the silicon nitride layers SN are etched in this part in the following. FIG. 9 is a top plan view schematically illustrating the silicon nitride layer SN in the stacked body SKI (see FIG. 5B, for example). When the etching solution is injected into the slits ST, the etching of the silicon nitride layers SN proceeds as illustrated by arrows A in FIG. 9. Namely, in the portion having no barrier layer BL, the silicon nitride layer SN is etched and the spaces SP spread. Because such an etching occurs in each one of the slits ST, the spaces SP spread from each slit ST, and then unite with one another within the finger area FG.

On the other hand, the etching of the silicon nitride layer SN also proceeds in a direction toward the edge portion STE of the slit ST from a terminating point EP of the barrier layer BL. Namely, as illustrated in FIG. 9, the silicon nitride layer SN is etched into a shape of quarter round around the terminating point EP. Therefore, the spaces SP are formed, even though the barrier layer BL is expected to prevent the etching in the portion indicated by the U4-U4 line in FIG. 9. With this, the sectional structure illustrated in FIG. 8B is obtained.

After the silicon nitride layers SN are removed, the electrically conductive layers WL are formed by filling the spaces SP with metal such as tungsten and the like using, for example, an atomic layer deposition (ALD) method. With this, the structure of the slit terminating area R described with reference to FIGS. 5A to 6E is completed.

### Comparative Example 1

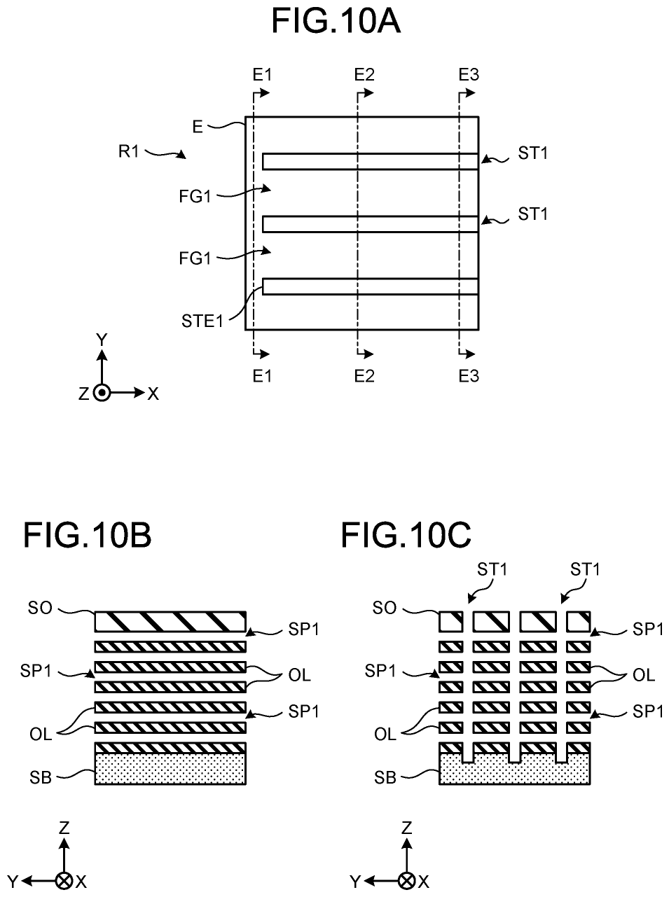

Next, referring to Comparative Example 1, an explanation is made on an effect brought about by the structure of the above-mentioned slit terminating area R. FIGS. 10A to 10C are explanatory drawings schematically illustrating a structure of a slit terminating area of the semiconductor storage device according to Comparative Example 1, and specifically illustrate a cross-section of the stacked body after the silicon nitride layer SN within the stacked body is etched, comparing with FIGS. 8A to 8C. FIG. 10A is a top plan view schematically illustrating a slit terminating area R1 in Comparative Example 1; FIG. 10B is a cross-sectional view taken along an E1-E1 line in FIG. 10A; FIG. 10C is a cross-sectional view taken along an E2-E2 line and also an E3-E3 line in FIG. 10A. Note that the slit terminating area R1 also has the stacking structure where the silicon oxide layers OL and the silicon nitride layers SN are stacked alternately one on the other before the etching of the silicon nitride layers SN.

As illustrated in FIG. 10A, plural slits ST1 are also provided in the slit terminating area R1 in Comparative Example 1. However, a layer corresponding to the barrier layer BL in the above-mentioned first embodiment is not formed in the slits ST1. Therefore, the silicon nitride layers SN are exposed on the inner surface of the slits ST1, and therefore the silicon nitride layers SN are removed as illustrated in FIG. 10C, and the spaces SP are formed. Additionally, the etching of the silicon nitride layers SN also proceeds toward the edge portion E of the stacked body portion from the edge portions STE1 of the slits ST1. With this, the spaces SP are also formed in a portion between the edge portions STE1 of the slits ST1 and the edge portion E of the stacked body portion as illustrated in FIG. 10B.

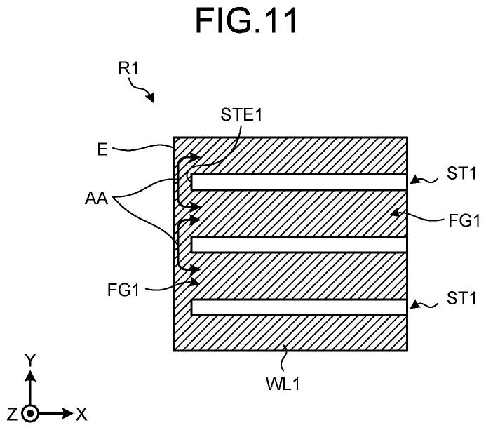

FIG. 11 is a top plan view schematically illustrating an electrically conductive layer WL1 of the slit terminating area R1 in Comparative Example 1. Namely, FIG. 11 illustrates the electrically conductive layer WL1 formed by filling metal such as tungsten and the like into the space SP. As illustrated in FIG. 11, because metal is also filled in a portion between the edge portions STE1 of the slits ST1 and the edge portion E of the stacked body portion, the finger areas FG are in electrical communication with one another through the electrically conductive layer WL as indicated by arrows AA in the drawing. In other words, a function of the slits ST1 to divide the finger areas FG1 electrically is impaired.

On the other hand, in the slit terminating area R of the semiconductor storage device 1 according to the embodiment, while the space SP extends from the terminating point EP of the barrier layer BL toward the edge portion STE of the slit ST, the space SP is spaced apart from the edge portion STE of the slit ST. Therefore, when the electrically conductive layer WL is formed by filling metal (e.g., tungsten) into the space SP, the boundary portion between the remaining silicon nitride layer SN and the electrically conductive layer WL is also spaced apart from the edge portion STE of the slit ST in the X-axis direction. In other words, the boundary portion between the silicon nitride layer SN and the electrically conductive layer WL is located farther from the edge portion STE of the slit ST with respect to the edge portion E of the stacked body portion along the X-axis direction. Therefore, the electrical path turning around the edge portion STE of the slit ST, the path being indicated by the arrows AA in FIG. 11, is not caused. Accordingly, electrical communication between the adjacent finger areas FG through the electrically conductive layer WL is prevented, and the electrical separation between the finger areas FG is maintained.

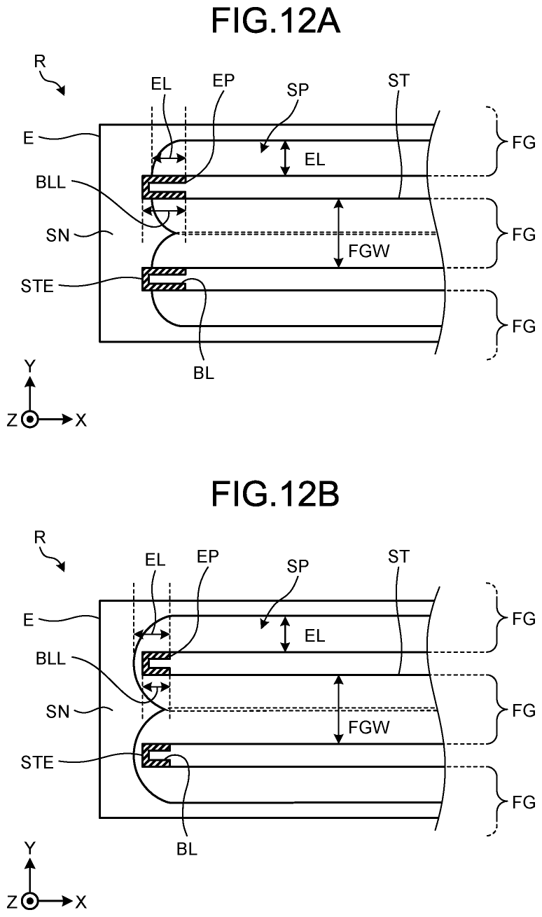

Note that a separation distance between the edge portion STE of the slit ST and the boundary portion between the silicon nitride layer SN and the electrically conductive layer WL depends on a length of the barrier layer BL formed on the inner surface of the slit ST along the X-axis direction. A relationship between the separation distance and the length of the barrier layer BL is described below. FIGS. 12A and 12B are top plan views schematically illustrating a relationship between the length of the barrier layer BL and an etching length of the silicon nitride layer SN etched through the slit ST.

As illustrated in FIG. 12A, while the silicon nitride layer SN is removed through the slit ST by injecting the etching solution into the slit ST and then the space SP is formed, the silicon nitride layer SN remains between the edge portion STE of the slit ST and the edge portion E of the stacked body portion. Here, to replace the silicon nitride layer SN with the electrically conductive layer WL in a portion sufficiently away from the edge portion STE of the slit ST, a relationship of 2×EL≥FGW is satisfied, wherein EL is the etching length of the silicon nitride layer SN, and FGW is a width of the finger area FG. Additionally, in order that the boundary portion between the silicon nitride layer SN and the electrically conductive layer WL formed by filling metal into the space SP is spaced apart from the edge portion STE of the slit ST, a relationship BLL>EL is satisfied, wherein BLL is a length from the edge portion STE of the slit ST to the terminating point EL of the barrier layer BL. This is clearly understood from FIG. 12B. Namely, when the etching length EL is longer than the length BLL of the barrier layer BL, the spaces SP extend beyond the edge portion STE of the slit ST and unite with each other on both sides of one slit ST. In this case, after the spaces SP are filled with metal, the adjacent finger areas FG become in electrical communication with one another.

Thus, the finger areas FG can be electrically isolated when the relationship of BLL>FGW/2 is satisfied between the length BLL of the barrier layer BL from the edge portion STE of the slit ST and the width FGW of the finger area FG. Additionally, a factor of safety may be taken into consideration. Namely, a relationship of BLL>FGW/2+Sf may be used, wherein Sf is a factor of safety.

### Comparative Example 2

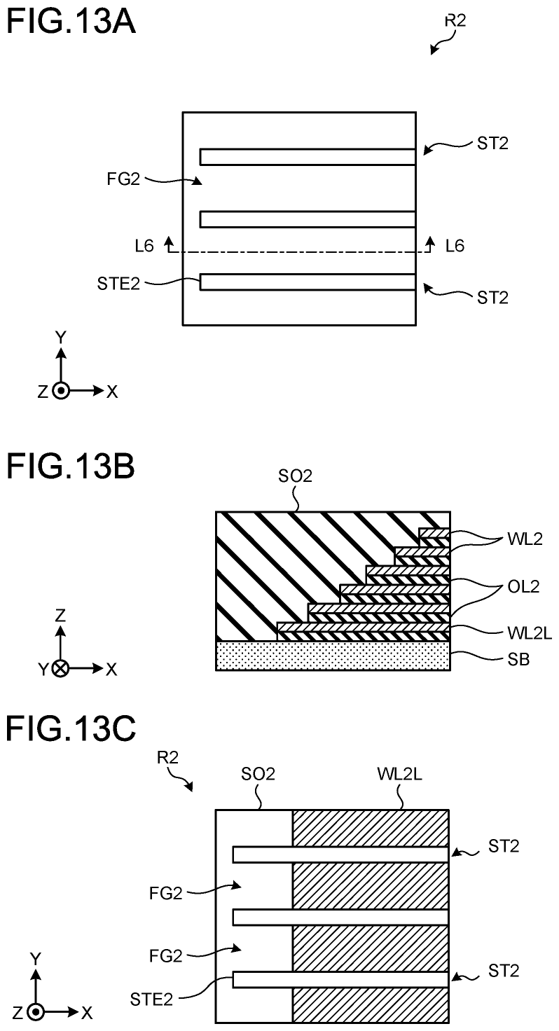

Then, referring to Comparative Example 2, an explanation is made on anther effect brought about by the structure of the above-mentioned slit terminating area R. FIG. 13A to FIG. 13C are explanatory views schematically illustrating a structure of a slit terminating area R2 of a semiconductor storage device according to Comparative Example 2. As illustrated in FIG. 13A, a layer corresponding to the barrier layer BL is not formed on an inner surface of a slit ST2. Additionally, FIG. 13B, which is a cross-sectional view taken along an L6-L6 line in FIG. 13A, illustrates electrically conductive layers WL2 arranged in a shape of stairs, and an inter-layer insulation layer SO2 that fills a space above the electrically conductive layers WL2. Such a shape is formed by processing a stacking structure where the silicon oxide layers OL2 and the silicon nitride layers (not illustrated) are stacked alternately one on the other into a shape of stairs, by depositing the silicon oxide film SO2, and then by replacing the silicon nitride layers with the electrically conductive layers WL2 through the slits ST2.

FIG. 13C is a top plan view schematically illustrating the lowermost electrically conductive layer WL2L illustrated in FIG. 13B. As illustrated in FIG. 13C, the slits ST2, which divide the stacked body portion, extend in the X-axis direction beyond a boundary portion between the silicon oxide film SO2 and the electrically conductive layer WL2L, and extend farther to an area above the base layer SB where the stacked structure is removed. Additionally, edge portions STE2 of the slits ST2 are located within the silicon oxide film SO2 rather than within the lowermost electrically conductive layer WL2L. Therefore, the electrical paths turning around the edge portions STE2 such as those indicated by the arrows AA in FIG. 11 are not caused. Hence, electrical communication between the adjacent finger areas FG is prevented by the structure according to Comparative Example 2. However, when short circuits between the adjacent finger areas FG2 is evaded by the shape of stairs such as Comparative Example 2, a length of the slit terminating area R2 along the X-axis direction becomes longer. Specifically, although only the six electrically conductive layers WL2 including the electrically conductive layer WL2L are illustrated in FIGS. 13A to 13C, the X-axis direction length of the slit terminating area R2 may be much longer when, for example, the number of the electrically conductive layers is 48 or 64.

On the other hand, according to the slit terminating area R of the semiconductor storage device 1 of the first embodiment, the shape of stairs at both ends of the stacking structure can be omitted. Therefore, a length of the slit terminating area R in the X-axis direction can be reduced, and thus the semiconductor storage device 1 can be downsized. Additionally, although contacts can be connected to the electrically conductive layers WL2 arranged in step shape in the slit terminating area R2 of Comparative Example 2, the contacts CC are connected to the corresponding electrically conductive layers WL in the above-mentioned stair portion FS, according to the semiconductor storage device 1. Because the stair portions FS are located in the center of the two memory array areas MA, respectively, an influence of parasitic resistance in each of the electrically conductive layers WL can be reduced, and the operation of the memory cells can be also speeded up.

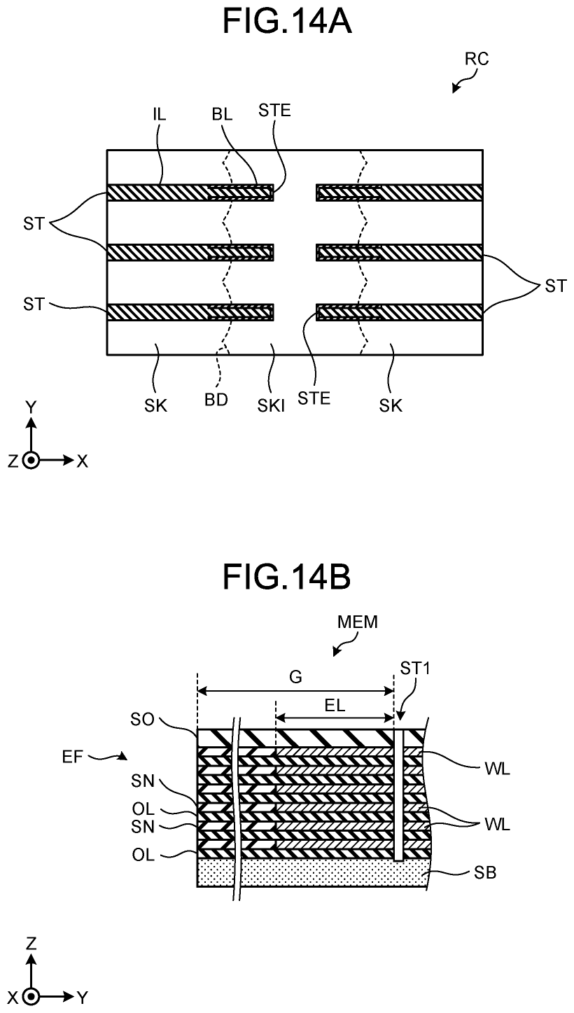

Then, referring to FIG. 14A, an explanation is made on a structure of a central portion of the semiconductor storage device 1 according to the first embodiment. FIG. 14A is a top plan view schematically illustrating a central portion of the semiconductor storage device 1. Here, the central portion corresponds to an area RC, which is illustrated in FIG. 1, between the two memory portions MEM of the semiconductor storage device 1. Additionally, three slits ST on the left hand side of FIG. 14A lead to three slits ST illustrated in FIG. 5A, respectively. Namely, FIG. 5A illustrates the edge portions STE of the slits ST on one end, and FIG. 14A illustrates the corresponding edge portions STE of the slits ST on the other end.

Note that the slits ST on the right hand side in FIG. 14A are formed in the memory portion MEM (see FIG. 1) on the right hand side of the semiconductor storage device 1. These slits ST have the edge portions STE spaced apart from the edge portions STE of the left slits ST, and extend along the X-axis direction. Because the right slit ST has a same structure as the left slit ST, the left slit ST is described in the following.

As illustrated in FIG. 14A, the barrier layer BL is provided on the inner surface of the slit ST. Specifically, the barrier layer BL covers a portion of the inner surface of the slit ST, the portion having a predetermined length from the edge portion STE of the slit ST along the X-axis direction. Such a barrier layer BL is formed as described referring to FIG. 7. Additionally, the barrier layer BL is provided in a proximity of the edge portion STE as described referring to FIGS. 8 and 9 to prevent the silicon nitride layer SN from being etched. Namely, the space formed by etching the silicon nitride layer SN is spaced apart from the edge portions STE of the slits ST. A boundary BD between the silicon nitride layer SN remaining in a proximity of the edge portion STE and the electrically conductive layer WL formed by filling metal into the space is also spaced apart from the edge portions STE of the slits ST. This boundary BD corresponds to a boundary between the stacked body SK and the stacked body SKI. Therefore, the stacked body SK and the stacked body SKI are arranged next to each other in the X-axis direction in the area RC, and the edge portions STE of the slits ST are located within the stacked body SKI. By such a structure, the electrical paths turning around the edge portions STE of the slits ST as indicated by the arrows AA in FIG. 11 are also prevented from being caused. Therefore, electrical communication between the adjacent finger areas FG through the electrically conductive layer WL are prevented, and thus electrical separation between the finger areas FG is maintained. Note that because the boundaries BD between the stacked body SK and the stacked body SKI in the central portion of the semiconductor storage device 1 are formed as explained with reference to FIG. 7, the boundaries BD are aligned in the stacking direction of the stacked bodies SK, SKI, as with those in FIG. 5A.

Then, referring to FIG. 14B, an explanation is made on a structure of the edge portion EF of the stacked body SKI, the edge portion EF extending in the X-axis direction. FIG. 14B is a partial cross-sectional view taken along a C1-C1 line in FIG. 1. As illustrated, the silicon oxide layers OL and the silicon nitride layers SN appear on the edge portion EF. The silicon nitride layers SN extend in the Y-axis direction to be connected to the corresponding electrically conductive layers WL, and boundary portions between the silicon nitride layers SN and the corresponding electrically conductive layers WL are located at a position between the edge portion EF of the stacked body SKI and the slit ST that is the nearest to the edge portion EF. Such a structure is formed by filling metal into the spaces formed by removing the silicon nitride layers SN using the etching solution injected into the slits ST. Here, a distance G between the edge portion EF and the slit ST nearest to the edge portion EF may be longer than an etching length EL. With this, the space SP formed by removing the silicon nitride layers SN do not reach the edge portion EF and allows the silicon nitride layers SN to remain at the edge portion EF. In other words, the edge portion EF (the edge portion 1X of the semiconductor storage device 1) of the stacked body SKI can prevent the electrically conductive layers WL from being exposed. Therefore, an unexpected electrical short can be prevented from occurring between upper and lower electrically conductive layers WL, for example, in a dicing process and the like performed later.

### Second Embodiment

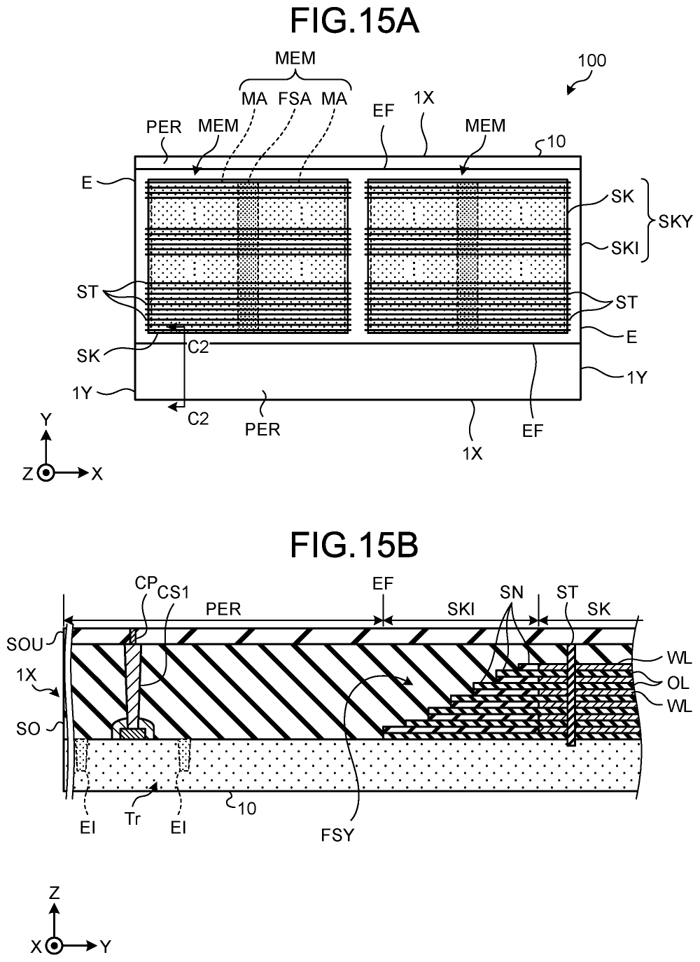

Next, referring to FIGS. 15A and 15B, an explanation is made on a semiconductor storage device according to a second embodiment. FIG. 15A is a top plan view schematically illustrating an example of a semiconductor storage device 100 according to the second embodiment; and FIG. 15B is a partial cross-sectional view taken along a C2-C2 line in FIG. 15A.

As illustrated in FIG. 15A, the semiconductor storage device 100 according to the second embodiment has a substrate 10. On the substrate 10, two peripheral circuit portions PER and a stacked body portion SKY are formed. Specifically, one of the peripheral circuit portions PER, the stacked body portion SKY, and the other one of the peripheral circuit portions PER are arranged in this order along the Y-axis direction on the substrate 10. Each of the peripheral circuit portions PER extends in an X-axis direction from one of edge portions 1Y, which extend along the Y-axis direction of the semiconductor storage device 100, to the other one of the edge portions 1Y. A length (width) of each one of the peripheral circuit portions PER along the Y-axis direction may be determined in consideration of, for example, peripheral circuits, electric lines, or the like to be formed in the peripheral circuit portions PER. The stacked body portion SKY is located between the two peripheral circuit portions PER and has the two stacked bodies SK and the stacked body SKI surrounding the two stacked bodies SK. As with the first embodiment, the memory portion MEM is formed in the stacked body SK. The memory portion MEM in this embodiment may have a structure substantially the same as the memory portion MEM of the semiconductor storage device 1 according to the first embodiment, except that at least a part of a structure of the peripheral circuit portions PER is not provided in a lower portion of the stacked body portion SKY. Note that when determining the length of the peripheral circuit portion PER in the Y-axis direction, the number of the memory cells in the memory array area MA of the memory portion MEM may be considered.

Additionally, both edge portions E extending along the Y-axis direction in the stacked body portion SKY correspond to the edge portions 1Y of the semiconductor storage device 100. In proximities of the edge portions E of the stacked body portion SKY, the slit terminating areas R are formed which are the same as those in the first embodiment (FIG. 5A and FIG. 5B). Namely, a boundary portion between the stacked body SKI and the stacked body SK extending from the edge portion E of the stacked body portion SKY (a boundary portion between the silicon nitride layer SN and the electrically conductive layer WL) is located farther from the edge portion STE of the slit ST along the X-axis direction with respect to the edge portion E of the stacked body portion SKY. On the other hand, both edge portions EF extending along the X-axis direction of the stacked body portion SKY are spaced apart from the edge portion 1X of the semiconductor storage device 100 by lengths of the peripheral circuit portions PER along the Y-axis direction, respectively.

Referring to FIG. 15B, the stacked body SKI has a stair portion FSY having a pair of the silicon nitride layer SN and the silicon oxide layer OL as one step, with the silicon nitride layers SN serving as terrace surfaces. The stair portion FSY may be formed when the stair portion FS in the above-mentioned stair area FSA is formed. Specifically, the stair portion FSY is formed by etching the stacked structure of the silicon nitride layers SN and the silicon oxide layers OL while slimming the photoresist mask used to form the stair portion FS.

On the other hand, the stacked body SK is formed by replacing partially the silicon nitride layers SN of the stacked body SKI with the electrically conductive layers WL through the slits ST before the slits ST are filled with an insulating material. In this embodiment, a part of the silicon nitride layers SN are allowed to remain when removing the silicon nitride layers SN through the slits ST, thereby to maintain the stacked body SKI. However, the silicon nitride layers SN may be removed to the edge portions of the corresponding steps of the stair portion FSY along the Y-axis direction, and then replaced with the electrically conductive layers WL. In other words, the stair portion that has the electrically conductive layers WL as the terrace surfaces may be provided in the edge portion EF of the stacked body portion SKY. Additionally, in the illustrated example, the silicon nitride layers SN are the terrace surfaces in the stair portion FSY, but the silicon oxide layers OL may be the terrace surfaces.

Note that the stair portion FSY formed on the side of the edge portion EF in the stacked body portion SKY may be processed into a shape of stairs of which slope is substantially equal to a slope of the shape of stairs at the stair portion FS in the stair area FSA (see FIG. 4) along the Y-axis direction, from the viewpoint of downsizing of the semiconductor storage device 100. The same is true on the shape of stairs formed on the side of the edge portion EF of the stacked body portion in each of embodiments described later.

Additionally, as illustrated in FIG. 15B, the peripheral circuit including the transistor Tr separated, for example, by the element-isolating portions EI is provided to the peripheral circuit portion PER. In the illustrated example, a gate contact CS1 penetrating through the inter-layer insulation layer SO is connected to the transistor Tr, and the gate contact CS1 is connected to a plug CP buried in an insulating film SOU as an upper layer of the inter-layer insulation layer SO. The plug CP is connected, for example, to the upper-layer lines (not illustrated).

Note that the semiconductor storage device 100 according to this embodiment can also have the stair area FSA similarly to the semiconductor storage device 1 according to the first embodiment. Thus, the gate contact CS1 may be electrically connected to the contact CC or the through-contact C4 (FIG. 2, FIG. 4) and the like through the plug CP and the upper-layer lines. However, in the semiconductor storage device 100, the less number of the through-contacts C4 may be provided in the stair area FSA than the number of the through-contacts C4 of the stair area FSA in the semiconductor storage device 1 according to the first embodiment. This is because the gate contacts CS1 may have the same function as that of the through-contacts C4. Additionally, in the semiconductor storage device 100, the stair area FSA may have no through-contacts C4.

Even in the semiconductor storage device 100 according to this embodiment, the boundary portion between the stacked body SKI and the stacked body SK (the boundary portion between the silicon nitride layer SN and the electrically conductive layer WL) is located farther from the edge portion STE of the slit ST with respect to the edge portion E of the stacked body portion SKY (stacked body SKI) along the X-axis direction. Therefore, the effect same as or similar to that described in the first embodiment by comparing the same with Comparative Example 1 and Comparative Example 2 is brought about even in the second embodiment. Additionally, a structure formed of the substrate 10 and an insulating material such as the inter-layer insulation layer SO, the insulating film SOU, or the like, appears on the edge portion 1X and the edge portion 1Y of the semiconductor storage device 100 according to this embodiment, and the electrically conductive layer WL does not appear thereon. Therefore, an unexpected electrical short can be prevented from occurring between upper and lower electrically conductive layers WL, for example, in a dicing process and the like performed later.

### Third Embodiment

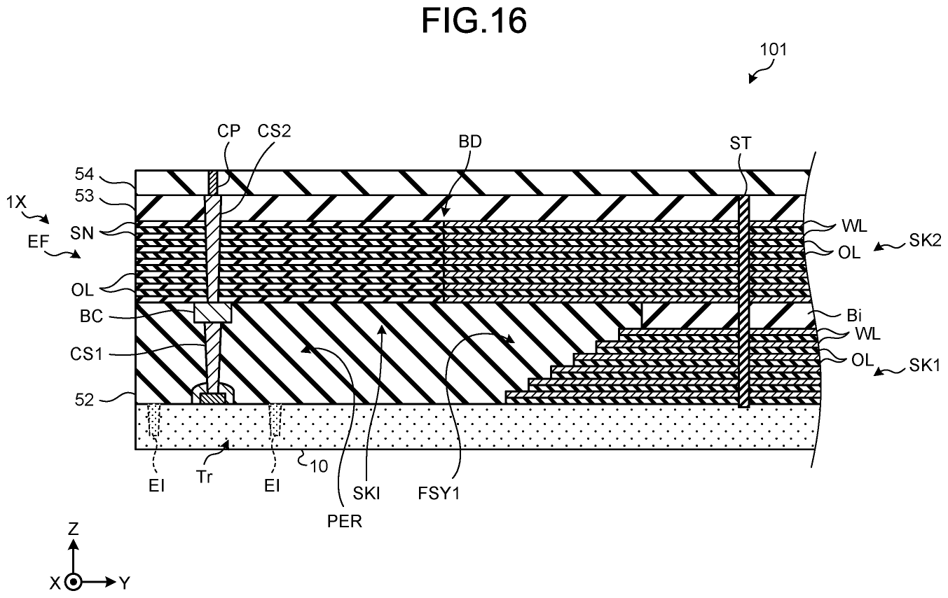

Next, referring to FIG. 16, an explanation is made on a semiconductor storage device according to a third embodiment. The semiconductor storage device according to the third embodiment is different from those according to the first and second embodiments in that the stacked body portion is provided in two tiers. FIG. 16 is a cross-sectional view taken along the Y-axis direction in a proximity of the edge portion 1X of a semiconductor storage device 101 according to this embodiment, and corresponds to, for example, the cross-sectional view (FIG. 15B) taken along the C2-C2 line in FIG. 15A.

As illustrated in FIG. 16, a stacked body SK1 has a structure where the silicon oxide layers OL and the electrically conductive layers WL are stacked alternately one on the other as with the above-mentioned stacked body SK. An edge portion of the stacked body SK1 in the Y-axis direction (corresponding to the edge portion EF (FIG. 15B) in the second embodiment) terminates at a position spaced apart from the edge portion 1X of the semiconductor storage device 101. The edge portion of the stacked body SK1 along the Y-axis direction is processed into a stair portion FSY1 having a pair of the electrically conductive layer WL and the silicon oxide layer OL as one step, with the electrically conductive layers WL serving as the terrace surfaces. However, the silicon oxide layers OL may be the terrace surfaces. Note that although not illustrated in FIG. 16, the above-mentioned memory portion MEM is formed in an area opposite to the edge portion 1X of the semiconductor storage device 101 with respect to the slits ST of the stacked body SK1.

Additionally, an insulating film 52 is formed to cover the stair portion FSY1 and the substrate 10. The insulating film 52 may be formed of, for example, an insulating material such as silicon oxide and the like. In the illustrated example, a transistor Tr, which is a part of peripheral circuits, is formed in a proximity of the interface between the substrate 10 and the insulating film 52. The gate contact CS1 and a junction portion BC on the gate contact CS1 is connected to the transistor Tr penetrating through the insulating film 52. Namely, on the substrate 10, the stacked body SK1 and the peripheral circuit portion PER are arranged next to each other in the Y-axis direction.

Additionally, a junction layer Bi is formed on the stacked body SK1. The junction layer Bi may be formed of, for example, silicon oxide. A top surface of the junction layer Bi is substantially coplanar with a top surface of the insulating film 52. The above-mentioned junction portion BC is arranged above the gate contact CS1 and at substantially the same elevation with the junction layer Bi along the Z-axis direction. The junction portion BC is formed of an electrically conductive material and connected to the gate contact CS1. The stacked body SKI and a stacked body SK2 are formed next to each other in the Y-axis direction on the junction portion BC, the insulating film 52, and the junction layer Bi. The stacked body SKI extends from a boundary BD between the stacked body SKI and the stacked body SK2 in the Y-axis direction, and reaches the edge portion 1X of the semiconductor storage device 101. Namely, the edge portion EF of the stacked body SKI corresponds to the edge portion 1X of the semiconductor storage device 101. Because the silicon oxide layers OL and the silicon nitride layers SN are stacked alternately one on the other in the stacked body SKI, the silicon oxide layers OL and the silicon nitride layers SN that are stacked alternately one on the other appear on the edge portion 1X of the semiconductor storage device 101.

The stacked body SK2 has a structure where the silicon oxide layers OL and the electrically conductive layers WL are stacked alternately one on the other as with the stacked body SK1, and is arranged above the stacked body SK1 with the junction layer Bi interposed therebetween. Although not illustrated, even in the stacked body SK2, the above-mentioned memory portion MEM is formed in an area opposite to the edge portion 1X of the semiconductor storage device 101 with respect to the illustrated slit ST. The memory portion MEM of the stacked body SK2 may be aligned along the Z-axis direction with the memory portion MEM of the stacked body SK1 below. In this case, although not illustrated in FIG. 16, the memory pillars MP (e.g., FIG. 3) in the memory array area MA of the memory portion MEM may be provided to penetrate through the stacked body SK1 and the stacked body SK2. Here, the electrically conductive layers WL of the stacked body SK2 function also as word lines. Therefore, the memory pillars MP can have the memory cells in both the stacked body SK1 and the stacked body SK2. Furthermore, the stair portion FS in the stair area FSA of the memory portion MEM can be also provided in the stacked body SK1 continually from the stacked body SK2. Note that the number of the through-contacts C4 provided in the stair area FSA may be less than the number of the through-contacts C4 of the stair area FSA in the semiconductor storage device 1 according to the first embodiment. Additionally, in the semiconductor storage device 101, no through-contacts C4 may be provided in the stair area FSA.

Additionally, as illustrated in FIG. 16, insulating films 53, 54 are formed of, for example, an insulating material such as silicon oxide and the like in this order on the stacked body SKI and the stacked body SK2. A contact CS2 is formed to penetrate through the insulating film 53 and the stacked body SKI and to connect with the junction portion BC. Additionally, the plug CP is formed to penetrate through the insulating film 54 and to connect with the contact CS2. The plug CP connects with the upper-layer lines (not illustrated), and the upper-layer lines connect with contacts and through-contacts in the stair area FSA in the memory portion MEM. With such a configuration, the memory cells in the memory array area MA are electrically connected to the peripheral circuits including transistor Tr.

Additionally, the slit ST is formed to penetrate through the insulating film 53, the stacked body SK2, the junction layer Bi, and the stacked body SK1, and to reach the substrate 10. The slit St is filled with an insulating material such as silicon oxide and the like. The slit ST is used to remove the silicon nitride layers SN before being filled with an insulating material, as described above. Although etching of the silicon nitride layers SN proceeds in the Y-axis direction by an etching solution injected into the slit ST, the etching does not reach the edge portion EF of the stacked body SKI, and thus the stacked body SKI remains in this embodiment. As a result, the stacked body SK2 and the stacked body SKI are arranged next to each other in the Y-axis direction. On the other hand, in the stacked body SK1, the silicon nitride layers SN are entirely replaced with the electrically conductive layers WL in the Y-axis direction, because a proceeding length of the etching is longer than a length of the lowermost silicon nitride layer SN before being replaced with the electrically conductive layer WL. Therefore, the stacked body SK1 has the structure where the silicon oxide layers OL and the electrically conductive layers WL are stacked alternately one on the other.

Note that the stacked bodies SKI are formed in both edge portions (corresponding to the edge portions E in the first and second embodiments) of the stacked body portion including the stacked body SK1 and the stacked body SK2 in the X-axis direction, and provided with the slit terminating areas R described referring to FIGS. 5 and 6. Namely, the boundary portion between the stacked body SK1 and the stacked body SKI is located farther from the edge portion of the slit ST along the X-axis direction with respect to the edge portion of the stacked body SKI in the X-axis direction. The boundary portion between the stacked body SK2 and the stacked body SKI is also located farther from the edge portion of the slit ST along the X-axis direction with respect to the edge portion of the stacked body SKI in the X-axis direction.

Therefore, the effect same as or similar to that described in the first embodiment by comparing the same with Comparative Example 1 and Comparative Example 2 is brought about even in the third embodiment. Additionally, the substrate 10, the silicon nitride layers SN, the insulating film 52 and the like appear on peripheral edge portions of the semiconductor storage device 101 according to this embodiment, and the electrically conductive layers WL do not appear thereon. Therefore, an unexpected electrical short can be prevented from occurring between upper and lower electrically conductive layers WL, for example, in a dicing process and the like performed later. Moreover, a storage capacity can be increased, because the semiconductor storage device 101 has the stacked body SK1 and the stacked body SK2 in two tiers in the Z-axis direction.

Modification 1 of Third Embodiment

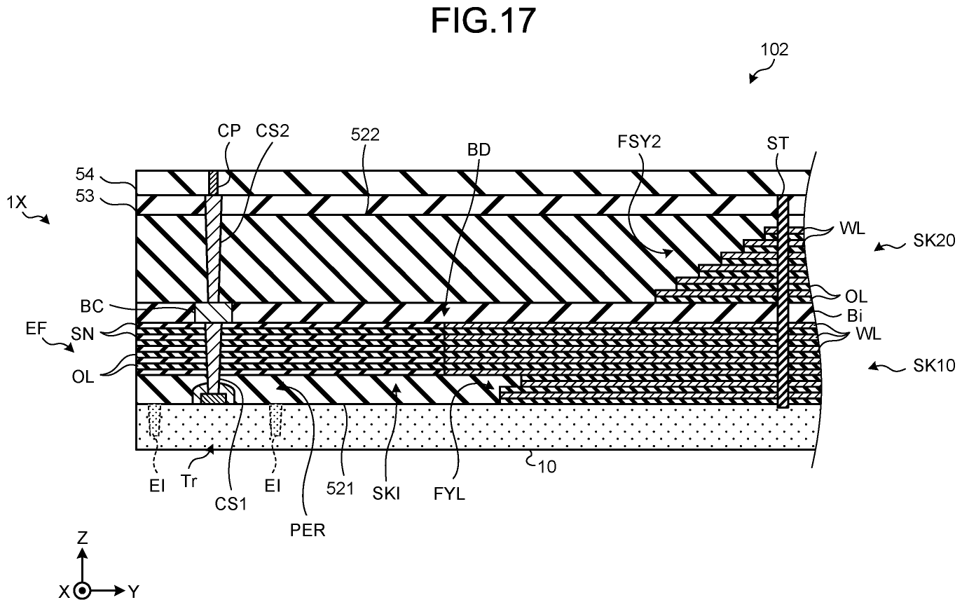

Next, referring to FIG. 17, an explanation is made on a semiconductor storage device 102 according to Modification 1 of the third embodiment. FIG. 17 is a cross-sectional view taken along the Y-axis direction in a proximity of the edge portion 1X of the semiconductor storage device 102 according to Modification 1 of the third embodiment. The semiconductor storage device 102 has a substrate 10, and a stacked body SK10 and an insulating film 521 are formed thereon. The stacked body SK10 has a structure where the silicon oxide layers OL and the electrically conductive layers WL are stacked alternately one on the other. A stair portion FYL is formed in an edge portion of a lower portion of the stacked body SK10 in the Y-axis direction. On the other hand, an upper-layer portion of the stacked body SK10 extends in the Y-axis direction and is connected to the stacked body SKI at a boundary BD on the insulating film 521. The stacked body SKI has a structure where the silicon oxide layers OL and the silicon nitride layers SN are stacked alternately one on the other. The edge portion EF of the stacked body SKI corresponds to the edge portion 1X of the semiconductor storage device 102 in Modification 1.

The stacked body SK10 also extends to an area opposite to the edge portion 1X of the semiconductor storage device 102 with respect to the slit ST. In the area, the memory portion MEM (not illustrated) is formed. The electrically conductive layers WL of the stacked body SK10 also function as word lines of the memory cells in the memory portion MEM. On the other hand, the transistor Tr, which is a part of the peripheral circuits, is formed at a boundary area between the insulating film 521 and the substrate 10 in the peripheral circuit portion PER. The gate contact CS1 penetrating through the stacked body SKI is connected to the transistor Tr. Also in the semiconductor storage device 102, the peripheral circuit portion PER and the memory portion MEM are arranged next to each other on the substrate 10 in the Y-axis direction.

The junction layer Bi is formed on the stacked body SKI and the stacked body SK10; and an insulating film 522 and a stacked body SK20 are formed on the junction layer Bi. The stacked body SK20 has a structure where the silicon oxide layers OL and the electrically conductive layers WL are stacked alternately one on the other as with the stacked body SK10 and is arranged above the stacked body SK10 with the junction layer Bi interposed therebetween. An edge portion of the stacked body 20 in the Y-axis direction (corresponding to the edge portion EF (FIG. 15B) in the second embodiment) terminates at a position spaced apart from the edge portion 1X of the semiconductor storage device 102. A stair portion FSY2 is formed in an edge portion of the stacked body SK20 in the Y-axis direction. The stair portion FSY2 has a pair of the electrically conductive layer WL and the silicon oxide layer OL as one-step, with the electrically conductive layers WL serving as terrace surfaces.

Additionally, on the stacked body SK20 and the insulating film 522, the insulating films 53, 54 are formed in this order. The slit ST is formed to penetrate through the insulating film 53, the stacked body SK20, the junction layer Bi, and the stacked body SK10 and to reach the substrate 10. The slit ST is used to replace the silicon nitride layers SN with the electrically conductive layers WL as mentioned above. In Modification 1 of the third embodiment, etching of the silicon nitride layers SN that proceeds in the Y-axis direction by an etching solution injected into the slit ST does not reach the edge portion EF of the stacked body SKI, and thus the stacked body SKI appears on the edge portion 1X of the semiconductor storage device 102. On the other hand, a proceeding length of the etching is longer than a length of the silicon nitride layer SN that has existed as the lowermost layer of the stacked boy SK20 in the Y-axis direction. Therefore, the stacked body SK20 has the structure where the silicon oxide layers OL and the electrically conductive layers WL are stacked alternately one on the other.

Additionally, the contact CS2 is formed to penetrate through the insulating film 53 and the insulating film 522. The contact CS2 is electrically connected to the gate contact CS1 through the junction portion BC. Additionally, the plug CP penetrating through the insulating film 54 is connected to an upper end of the contact CS2. With this, the transistor Tr and, for example, the contacts of the stair area FSA (not illustrated) are electrically connected.

The stacked bodies SKI are formed in both edge portions (corresponding to the edge portions E in the first embodiment and the second embodiment) of the stacked body portion including the stacked body SK10 and the stacked body SK20 in the X-axis direction, and provided with the slit terminating areas R described referring to FIGS. 5 and 6. Namely, the boundary portion between the stacked body SK10 and the stacked body SKI is located farther from the edge portion of the slit ST along the X-axis direction with respect to the edge portion of the stacked body SKI in the X-axis direction. The boundary portion between the stacked body SK20 and the stacked body SKI is also located farther from the edge portion of the slit ST along the X-axis direction with respect to the edge portion of the stacked body SKI in the X-axis direction.

Therefore, the effect same as or similar to that described in the first embodiment by comparing the same with Comparative Example 1 and Comparative Example 2 is brought about even in Modification 1 of the third embodiment. Additionally, the electrically conductive layers WL do not appear on a peripheral edge portion of the semiconductor storage device 102 according to Modification 1. Therefore, an unexpected electrical short can be prevented from occurring between upper and lower electrically conductive layers WL, for example, in a dicing process and the like performed later. Moreover, a storage capacity can be increased, because the semiconductor storage device 102 has the stacked body SK10 and the stacked body SK20 in two tiers in the Z-axis direction.

Modification 2 of Third Embodiment

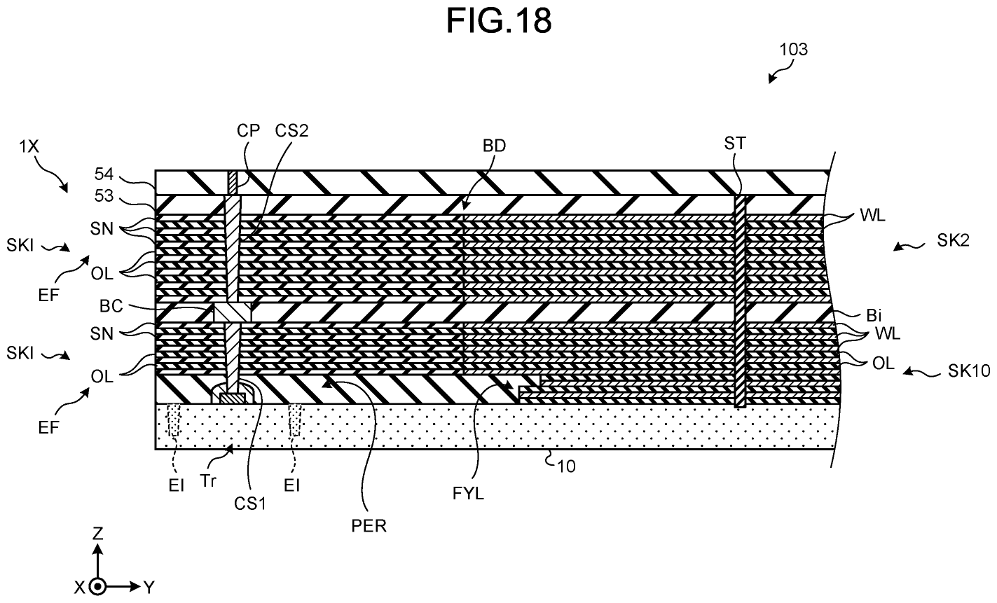

Next, referring to FIG. 18, an explanation is made on a semiconductor storage device 103 according to Modification 2 of the third embodiment. FIG. 18 is a cross-sectional view taken along the Y-axis direction in a proximity of the edge portion 1X of the semiconductor storage device 103 according to Modification 2 of the third embodiment. As illustrated in FIG. 18, the semiconductor storage device 103 has the substrate 10. On the substrate 10, a first tier structure of the semiconductor storage device 102 according to Modification 1 and a second tier structure of the semiconductor storage device 101 according to the third embodiment are arranged as a stacked body portion. In such a structure, the stacked body SK2 and the stacked body SKI in the second tier are connected with each other, and the stacked body SK10 and the stacked body SKI in the first tier are also connected with each other at the boundary BD. The edge portion EF of the stacked body SKI appears on the edge portion 1X of the semiconductor storage device 103.

The stacked bodies SKI are formed in both edge portions (corresponding to the edge portions E in the first embodiment and the second embodiment) of the stacked body portion including the stacked body SK10 and the stacked body SK2 in the X-axis direction, and provided with the slit terminating areas R described referring to FIGS. 5 and 6. Namely, the boundary portion between the stacked body SK10 and the stacked body SKI is located farther from the edge portion of the slit ST along the X-axis direction with respect to the edge portion of the stacked body SKI in the X-axis direction. The boundary portion between the stacked body SK2 and the stacked body SKI is also located farther from the edge portion of the slit ST along the X-axis direction with respect to the edge portion of the stacked body SKI in the X-axis direction. Therefore, the effect same as or similar to that described in the first embodiment by comparing the same with Comparative Example 1 and Comparative Example 2 is brought about even in Modification 2 of the third embodiment. Additionally, the electrically conductive layers WL do not appear on a peripheral edge portion of the semiconductor storage device 103. Therefore, an unexpected electrical short can be prevented from occurring between upper and lower electrically conductive layers WL, for example, in a dicing process and the like performed later. Moreover, a storage capacity can be increased, because the semiconductor storage device 103 has the stacked body SK10 and the stacked body SK2 in two tiers in the Z-axis direction.

First Modification

Next, an explanation is made on First Modification of the semiconductor storage devices 1, 100, 101 (102,103) according to the first, the second, and the third embodiments, respectively. The semiconductor storage device according to First Modification is different from each one of the semiconductor storage devices according to the above-mentioned embodiments in that a stair area is different from the above-mentioned stair area FSA, and other structures are the same as those in the previous embodiments. In the following, an explanation is made on the semiconductor storage device according to First Modification, focusing on the differences with respect to the semiconductor storage device 1 according to the first embodiment.

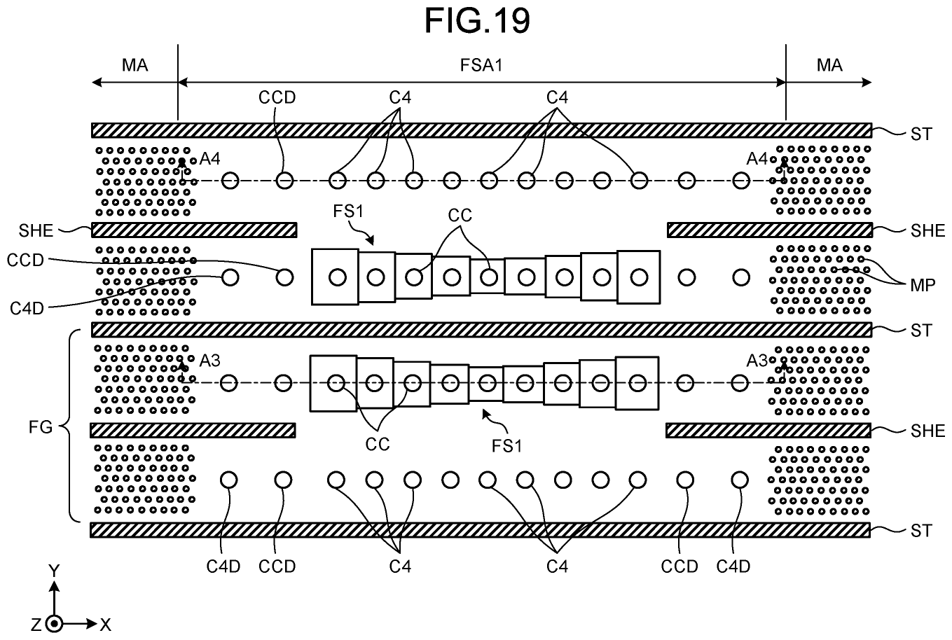

FIG. 19 is a top plan view schematically illustrating a stair area FSA1 of the semiconductor storage device according to First Modification. The stair area FSA1 corresponds to the stair area FSA arranged in the memory portion MEM illustrated in FIG. 1. Namely, the memory array areas MA are provided on both sides of the stair area FSA1. As illustrated in FIG. 19, the stair area FSA1 and the memory array areas MA are divided by slits ST extending in the X-axis direction, even in the semiconductor storage device according to First Modification. An area divided by the two adjacent slits ST is called a finger area FG in accordance with that in FIG. 2. Each one of the finger areas FG is provided with a stair portion FS1 extending in the X-axis direction and a group of the through-contacts C4 that are aligned with corresponding terrace surfaces of the stair portion FS1 in the Y-axis direction. Note that the contacts CC on the corresponding ones of the terrace surfaces and the through-contacts C4 are connected with each other by upper-layer lines (not illustrated).

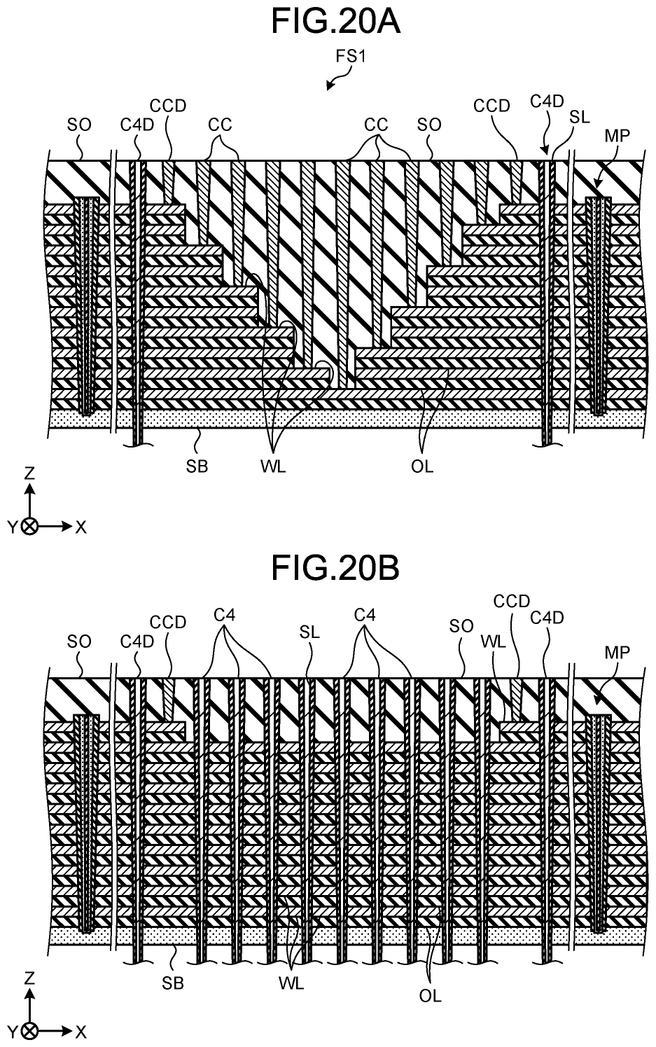

FIG. 20A is a cross-sectional view taken along an A3-A3 line in FIG. 19. As illustrated, the stair portion FS1 is formed by the silicon oxide layers OL and the electrically conductive layers WL, with the electrically conductive layers WL serving as terrace surfaces. The stair portion FS1 is different from the stair portion FS (FIG. 3) in, for example, the semiconductor storage device 1 according to the first embodiment. Namely, the stair portion FS1 has a lowest step at the center and other steps elevated step-by-step along directions away from the center. More specifically, the stair portion FS1 has the second electrically conductive layer WL, the fourth step electrically conductive layer WL, the sixth electrically conductive layer WL, . . . , from the bottom, which serve as respective terrace surfaces, in one direction from the lowest step having the first electrically conductive layer WL as the terrace surface, along the X-axis direction. Additionally, the stair portion FS1 has the third electrically conductive layer WL, the fifth electrically conductive layer WL, the seventh electrically conductive layer WL, . . . , from the bottom, which serve as respective terrace surfaces in the other direction from the lowest step along the X-axis direction. The contacts CC penetrating through the inter-layer insulation layer SO are connected to the corresponding terrace surfaces of the steps. Note that the silicon oxide layers OL may serve as the terrace surfaces. In this case, the contacts CC penetrate through the inter-layer insulation layer SO and the silicon oxide layers OL as the terrace surfaces, thereby to connect to the corresponding electrically conductive layers WL.

Such a stair portion FS1 can be formed by a processing method that is similar to that for the stair portion FS in the semiconductor storage device 1 according to the first embodiment. For example, a stacking structure where the silicon oxide layers OL and the silicon nitride layers SN are stacked alternately one on the other is formed, as with the stacked body SKI, on the semiconductor base SB. Next, a photoresist mask is provided which has openings in positions where the stair portions FS1 are to be formed; and processes are performed which include etching using the photoresist mask, and slimming of the photoresist mask, and additional etching using the slimmed photoresist mask. With this, a preliminary stair portion is formed which has the silicon nitride layers SN as the terrace surfaces. After this, the silicon nitride layers SN are replaced with the electrically conductive layers WL, and thus the stair portion FS1 is obtained.

Additionally, in FIG. 20A, contacts CCD are connected to the corresponding uppermost electrically conductive layers WL. Intersecting portions of the uppermost electrically conductive layers WL and the memory pillars MP constitute drain select transistors, and in other words, the uppermost electrically conductive layers WL function as drain select gate lines. Additionally, through-contacts C4D are provided adjacent to the corresponding contacts in the X-axis direction. The through-contacts C4D penetrate through the silicon oxide layers OL and the electrically conductive layers WL and reach the peripheral circuit portion PER (not illustrated). The through-contacts C4D are electrically connected at the lower ends with the peripheral circuits of the peripheral circuit portion PER, and, at the upper ends with the upper end of the contacts CCD through unillustrated upper-layer lines. With this, the drain select transistor is controlled by the peripheral circuits through the through-contacts C4D and the corresponding contacts CCD.

Note that the through-contact C4D has a spacer layer SL formed of an insulating material as an outer peripheral surface thereof, and the inner electrically conductive portion is insulated from the electrically conductive layers WL by the spacer layer SL.

FIG. 20B is a cross-sectional view taken along an A4-A4 line in FIG. 19. As illustrated in FIG. 20B, a group of the through-contacts C4 are formed which penetrate through the silicon oxide layers OL and the electrically conductive layers WL and reach the peripheral circuit portion PER (not illustrated). The through-contacts C4 are also provided with the spacer layer SL, and thus electrically conductive portions in the centers of the through-contacts C4 are insulated from the electrically conductive layers WL. Additionally, even in FIG. 20B, the contact CCD and the through-contact C4D are provided on both sides of the group of the through-contacts C4 along the X-axis direction. A pair of the through-contact C4D and the contact CCD that are arranged next to each other in the X-axis direction are electrically connected to each other through unillustrated upper-layer lines.

Referring again to FIG. 19, slits SHE are provided at substantially the central portions of the finger areas FG in the Y-axis direction. The slits SHE extend in the X-axis direction in the memory array area MA and the stair area FSA1, except in an area between the stair portion FS1 and the group of the through-contacts C4. The slits SHE divide only the uppermost electrically conductive layer WL (drain select gate line) differently from the slits ST that penetrate throughout the stacked body SK. With this, the drain select transistors are formed respectively on both sides of the slit SHE. On the other hand, because the electrically conductive layers WL below the uppermost electrically conductive layer WL are not divided by the slit SHE, the electrically conductive layers WL extend throughout the finger area FG, thereby to be shared by all the memory pillars MP in the same finger area FG. Therefore, the contacts CC connected to the corresponding electrically conductive layers WL are also shared by the memory pillars MP in the same finger area FG. Namely, while the memory cells located at the same level within the same finger area FG share one of the contacts CC (and then the corresponding through-contacts C4 electrically connecting thereto) so as to be operated through the same electrically conductive layer WL (word line), the drain select transistors on both sides of the slit SHE operate independently by the corresponding drain select gate lines divided by the slit SHE.

The semiconductor storage device according to First Modification is provided with the stair area FSA1 that is different from the semiconductor storage device 1 according to the embodiment as above, but the semiconductor storage device according to First Modification can also have the structure of the above-mentioned slit terminating area R. Namely, the effect same as or similar to the effect explained above is provided by the slit terminating area R even in the semiconductor storage device according to First Modification.

Note that the stair area FSA (FIG. 2) may be applied to one of the two memory portions MEM provided in the semiconductor storage device 1 according to the first embodiment, and the stair area FSA1 (FIG. 19) may be applied to the other one of the two memory portions MEM. Alternatively, the stair area FSA or the stair area FSA1 may be applied to both of the two memory portions MEM of the semiconductor storage device 1 according to the first embodiment. Additionally, the stair area FSA1 in First Modification may be provided in the semiconductor storage devices 100, 101 (102,103) according to the second and third embodiments in the place of the stair area FSA. Even in this case, the stair area FSA1 may be also provided in both or either one of the two memory portions MEM. However, the number of the through-contacts C4 may be reduced than the number of the through-contacts C4 in the semiconductor storage device 1 according to the first embodiment.

Second Modification

Next, an explanation is made on Second Modification of the semiconductor storage devices 1, 100, 101 (102,103) according to the first, the second, and the third embodiment, respectively. The semiconductor storage device according to Second Modification is different from the semiconductor storage device 1 in that the above-mentioned electrically conductive layers WL have liner layers, and the other structure is the same. Focusing on such a difference, the semiconductor storage device according to Second Modification is explained in the following.

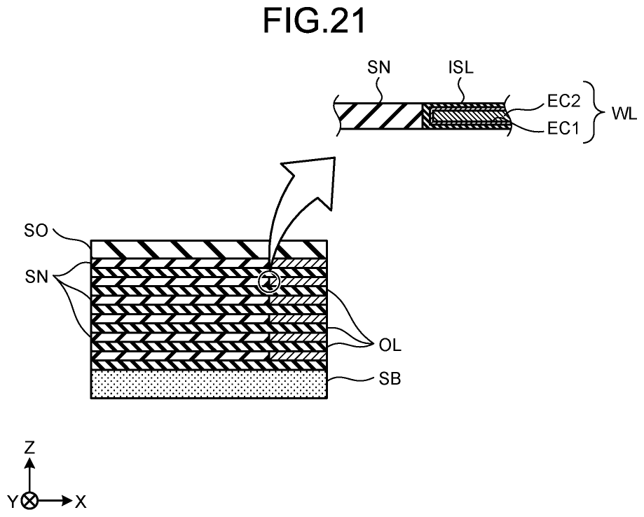

FIG. 21 is a cross-sectional view schematically illustrating a slit terminating area in Second Modification, and corresponds to FIG. 5B. Referring to an expanded portion of FIG. 21, the electrically conductive layer WL is formed within a liner layer ISL. The liner layer ISL may be formed of, for example, an insulating material such as aluminum oxide (Al₂O₃) and the like. Additionally, in the illustrated example, the electrically conductive layer WL includes a first electrically conductive portion EC1 inside the liner layer ISL, and a second electrically conductive portion EC2 inside the first conductive portion EC1. The first electrically conductive portion EC1 may be formed of, for example, titanium nitride (TiN), and the second electrically conductive portion EC2 may be formed of, for example, tungsten (W). Such a structure may be formed by removing the silicon nitride layers SN through slits ST (omitted in FIG. 21) thereby to form spaces SP (e.g., FIG. 8), and depositing on an inner surface of the spaces SP the liner layer ISL, the first electrically conductive portion EC1, the second electrically conductive portion EC2 in this order. The liner layer ISL and the first electrically conductive portion EC1 may serve as barrier layers.

Other Modifications

The semiconductor storage device according to the above-mentioned third embodiment (including Modifications 1, 2) has the stacked bodies SK1, SK2 in two tiers, but not limited thereto. The semiconductor storage device may include the stacked bodies in three or more tiers. Additionally, the stacking number of each stacked body may be determined arbitrarily, without being limited to examples illustrated.

The semiconductor storage devices according to the above-mentioned first to the third embodiments (including Modifications) have the two memory portions MEM, but the number of the memory portions MEM may be three or more, and may be determined arbitrarily, without being limited to this.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a stacked body in which a plurality of first layers and a plurality of second layers are stacked alternately one on another; and
a plurality of plate-like portions that penetrate through the stacked body in a stacking direction of the stacked body and extend in a first direction intersecting the stacking direction,
wherein
the plurality of first layers are formed of a first insulating material, and
each of the plurality of second layers includes a first insulating area and an electrically conductive area,
the first insulating area being arranged to extend from a first edge portion of the stacked body in the first direction so that the first insulating area occupies at least an area between a first edge portion of each of the plurality of plate-like portions extending in the first direction and the first edge portion of the stacked body in the first direction, the first insulating area being formed of a second insulating material, and
the electrically conductive area being connected to the first insulating area in the first direction, and
a boundary portion between the first insulating area and the electrically conductive area is located farther from the first edge portion of each of the plurality of plate-like portions along the first direction with respect to the first edge portion of the stacked body.

2. The semiconductor storage device according to claim 1,
wherein
each of the plurality of second layers further includes a second insulating area that is connected to the electrically conductive area on the opposite side of the first insulating area such that the electrically conductive area is located between the first and second insulating areas, the second insulating area being formed of the second insulating material, and
a second edge portion of each of the plurality of plate-like portions, the second edge portion being opposite to the first edge portion thereof, is located farther from a boundary portion between the electrically conductive area and the second insulating area with respect to the first edge portion of the stacked body.

3. The semiconductor storage device according to claim 1,
wherein
boundary portions between a plurality of the first insulating areas and corresponding ones of a plurality of the electrically conductive areas in the plurality of second layers are aligned in the stacking direction.

4. The semiconductor storage device according to claim 2,
wherein
boundary portions between a plurality of the second insulating areas and corresponding ones of a plurality of the electrically conductive areas in the plurality of second layers are aligned in the stacking direction.

5. The semiconductor storage device according to claim 1,
wherein
each of the plurality of plate-like portions includes an electrically insulating barrier layer that extends by a predetermined length from the first edge portion of each of the plurality of plate-like portions in the first direction.

6. The semiconductor storage device according to claim 5,
wherein
a relationship of BLL>FGW/2 is satisfied,
where
BLL is the predetermined length of the barrier layer that extends in the first direction, and
FGW is a distance between two adjacent ones of the plurality of plate-like portions.

7. The semiconductor storage device according to claim 1,
wherein
each of the plurality of second layers further includes a third insulating area formed of the second insulating material, the third insulating area being connected to the electrically conductive area in a second direction intersecting the first direction and the stacking direction.

8. The semiconductor storage device according to claim 7,
wherein
the third insulating area of each of the plurality of second layers extends in the second direction, and appears on a second edge portion intersecting the first edge portion of the stacked body.

9. The semiconductor storage device according to claim 7,
wherein
a plurality of the third insulating areas the plurality of second layers are formed in a shape of stairs that descend in the second direction.

10. The semiconductor storage device according to claim 1,
wherein
the stacked body has a first area, a second area, and a third area arranged along the first direction, each of the plurality of second layers in the first through third areas including the electrically conductive area,
a plurality of the electrically conductive areas in the plurality of second layers are formed in a shape of stairs in the second area of the stacked body, connecting portions being connected to corresponding ones of the electrically conductive areas in the second area of the stacked body, and
the first and third areas are provided with a plurality of pillar portions that penetrate through the stacked body in the stacking direction, the plurality of pillar portions having a plurality of memory cells formed in positions where the plurality of pillar portions intersect at least a part of a plurality of the electrically conductive areas in the plurality of second layers.

11. The semiconductor storage device according to claim 10, wherein
each of the plurality of second layers locally includes a fourth insulating area formed of the second insulating material in the second area, and
a plurality of the fourth insulating areas in the plurality of second layers are aligned in the stacking direction.

12. The semiconductor storage device according to claim 11, wherein
the fourth insulating areas are arranged next to the electrically conductive areas formed in the shape of stairs, in the first direction, between two adjacent ones of the plurality of plate-like portions in the second area.

13. The semiconductor storage device according to claim 11, further comprising a through-contact portion that penetrates through the fourth insulating areas in the stacking direction.

14. The semiconductor storage device according to claim 10, wherein the shape of stairs ascend or descend in the first direction.

15. The semiconductor storage device according to claim 10, wherein the shape of stairs ascend and descend in the first direction.

16. The semiconductor storage device according to claim 10, further comprising a peripheral circuit portion that includes a control circuit configured to control the plurality of memory cells, the peripheral circuit portion being provided below the staked body in the stacking direction.

17. The semiconductor storage device according to claim 1, further comprising at least one additional one of the stacked body so that at least two of a plurality of the stacked bodies are stacked in two tiers.

18. The semiconductor storage device according to claim 7,
wherein
each of the plurality of second layers in at least one of the stacked bodies further includes a fifth insulating area formed of the second insulating material, the fifth insulating area being connected to the electrically conductive area in a second direction intersecting the first direction and the stacking direction.

19. The semiconductor storage device according to claim 18, wherein
the fifth insulating area of each of the plurality of second layers in the at least one of the stacked bodies extends in the second direction and appears on a second edge portion of the stacked bodies, the second edge portion intersecting the first edge portion of the stacked body.

20. The semiconductor storage device according to claim 19, wherein
each of the plurality of second layers in another one of the stacked bodies terminates in a position spaced apart from the second edge portion of the stacked bodies along the second direction.
